(19) United States
(12) Patent Application Publication
(10) Pub. No.: US 2026/0314236 A1
(43) Pub. Date: Oct. 8, 2026

(54) DISPLAY DEVICE AND ELECTRONIC APPARATUS INCLUDING THE DISPLAY DEVICE

(71) Applicant: Samsung Display Co., LTD., Yongin-si (KR)

(72) Inventors: Sangwoo KIM, Yongin-si (KR); Myunghee HAN, Yongin-si (KR)

(21) Appl. No.: 19/456,679

(22) Filed: Jan. 22, 2026

(30) Foreign Application Priority Data
Jan. 22, 2025 (KR) 10-2025-0009817

(51) Int. Cl. H10K 59/80

(52) U.S. Cl. CPC H10K 59/873

(57) ABSTRACT

A display device includes a first island portion and first bridge portions extending in different directions from the first island portion. The display device includes a substrate including a first portion corresponding to the first island portion and second portions corresponding to the plurality of first bridge portions, a pixel driving circuit on the substrate, a light-emitting element on the pixel driving circuit, a first inorganic encapsulation layer on the light-emitting element, a first layer between the pixel driving circuit and the first electrode of the light-emitting element, and a second layer on the first layer. A portion of the second layer extends in a direction away from an upper surface of the first layer and has a first angle with respect to the upper surface of the first layer. A first surface of the second layer is in direct contact with the first inorganic encapsulation layer.

### CROSS-REFERENCE TO RELATED APPLICATION

This application claims priority to Korean Patent Application No. 10-2025-0009817, filed on Jan. 22, 2025, and all the benefits accruing therefrom under 35 U.S.C. §119, the content of which in its entirety is herein incorporated by reference.

### BACKGROUND

### 1. Field

Embodiments of the present disclosure relate to a display device and an electronic apparatus including the display device.

### 2. Description of the Related Art

With the development of display devices that visually display electrical signals, various display devices having excellent characteristics, such as thinness, light weight, and low power consumption, have been introduced. For example, flexible display devices that may be folded or rolled up have been introduced. Recently, research and development on display devices having various structures, such as stretchable display devices that may be changed into various shapes, have been actively conducted.

### SUMMARY

Embodiments of the present disclosure provide a display device and an electronic apparatus including the display device.

Additional aspects will be set forth in part in the description which follows and, in part, will be apparent from the description, or may be learned by practice of the presented embodiments of the disclosure.

An embodiment of the present disclosure discloses a display device including a first island portion; a plurality of first bridge portions extending in different directions from the first island portion; a substrate including a first portion corresponding to the first island portion and a plurality of second portions corresponding to the plurality of first bridge portions; a pixel driving circuit arranged on the first portion of the substrate; a light-emitting element arranged on the pixel driving circuit and including a first electrode electrically connected to the pixel driving circuit, a second electrode arranged on the first electrode, and an intermediate layer arranged between the first electrode and the second electrode; a first inorganic encapsulation layer arranged on the light-emitting element; a first layer interposed between the pixel driving circuit and the first electrode of the light-emitting element and including an inorganic insulating material; and a second layer arranged on the first layer and including a portion extending in a direction away from an upper surface of the first layer, a first surface facing the first layer, and a second surface opposite to the first surface, wherein the first surface is in direct contact with the first inorganic encapsulation layer.

The second layer may include an inorganic insulating material.

The second layer may include a metal material.

The second electrode of the light-emitting element may extend toward the second layer, and may be in direct contact with a portion of the first surface of the second layer.

The second layer may have a constant voltage level.

When viewed in a direction perpendicular to the substrate, the second layer may have a frame shape extending along an edge of the first island portion.

A first angle between the portion of the second layer and the upper surface of the first layer may be about 45 degrees or less.

The upper surface of the first layer may faces the first surface of the second layer, and the first inorganic encapsulation layer may extend continuously and cover the first surface of the second layer and the upper surface of the first layer.

The display device may further include: an organic encapsulation layer on the first inorganic encapsulation layer; and a second inorganic encapsulation layer on the organic encapsulation layer, wherein the second inorganic encapsulation layer may be in direct contact with the first inorganic encapsulation layer on the first surface of the second layer.

The first inorganic encapsulation layer and the second inorganic encapsulation layer may extend toward the plurality of first bridge portions, and may be in direct contact with each other on the plurality of second portions of the substrate.

A peripheral portion of the first layer may extend in a direction away from the first surface of the second layer.

An embodiment of the present disclosure discloses an electronic apparatus including: a display unit, a frame; and a display device which is assembled to the frame, corresponds to the display unit, and includes: a first island portion; a plurality of first bridge portions extending in different directions from the first island portion, a substrate including a first portion corresponding to the first island portion and a plurality of second portions corresponding to the plurality of first bridge portions; a pixel driving circuit arranged on the first portion of the substrate; a light-emitting element arranged on the pixel driving circuit and including: a first electrode electrically connected to the pixel driving circuit, a second electrode arranged on the first electrode, and an intermediate layer arranged between the first electrode and the second electrode; a first inorganic encapsulation layer arranged on the light-emitting element; a first layer interposed between the pixel driving circuit and the first electrode of the light-emitting element; and a second layer arranged on the first layer and including: a portion extending upward from a first point; a first surface facing the first layer; and a second surface opposite to the first surface, wherein the first surface is in direct contact with the first inorganic encapsulation layer.

The electronic apparatus may further include a stroke assembled to the frame and arranged between the display device and the frame.

The second layer may include an inorganic insulating material.

The second layer may include a metal material and may have a constant voltage level.

The second electrode of the light-emitting element may extend toward the second layer and may be in direct contact with a portion of the first surface of the second layer.

When viewed in a direction perpendicular to the substrate, the second layer may have a frame shape extending along an edge of the first island portion.

A peripheral portion of the second layer may extend downward.

The first layer may include a first surface facing the first surface of the second layer, and the first inorganic encapsulation layer may extend continuously and cover the first surface of the second layer and the first surface of the first layer.

The display device may further include: an organic encapsulation layer on the first inorganic encapsulation layer; and a second inorganic encapsulation layer on the organic encapsulation layer, wherein the second inorganic encapsulation layer may be in direct contact with the first inorganic encapsulation layer on the first surface of the second layer.

The first inorganic encapsulation layer and the second inorganic encapsulation layer may extend toward the plurality of first bridge portions, and may be in direct contact with each other on the plurality of second portions of the substrate.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display device according to an embodiment of the present disclosure;

FIGS. 2A and 2B are perspective views of a state in which the display device of FIG. 1 is stretched in a first direction;

FIG. 2C is a perspective view of a state in which the display device of FIG. 1 is stretched in a second direction;

FIG. 2D is a perspective view of a state in which the display device of FIG. 1 is stretched in the first direction and the second direction;

FIG. 2E is a perspective view of a state in which the display device of FIG. 1 is stretched in a third direction;

FIG. 3 is a schematic plan view of a display device according to an embodiment of the present disclosure;

FIG. 4A is an enlarged plan view of region IV of FIG. 3 as a portion of a display device according to an embodiment of the present disclosure;

FIG. 4B is an enlarged plan view of the region IV of FIG. 3 as a portion of a display device according to an embodiment of the present disclosure;

FIG. 4C is an enlarged plan view of the region IV of FIG. 3 as a portion of a display device according to an embodiment of the present disclosure;

FIG. 4D is an enlarged plan view of a portion of a display area of FIG. 3 as a portion of a display device according to an embodiment of the present disclosure;

FIG. 4E is an enlarged plan view of the region IV of FIG. 3 as a portion of a display device according to an embodiment of the present disclosure;

FIG. 5 is a schematic cross-sectional view of a first island portion and a first bridge portion that are arranged in a display area of a display device, according to an embodiment of the present disclosure;

FIGS. 6A to 6C are each an equivalent circuit diagram of a sub-pixel of a display device according to an embodiment of the present disclosure;

FIG. 7 is a plan view of a portion of a display device according to an embodiment of the present disclosure;

FIG. 8 is a cross-sectional view taken along line VIII-VIII' of FIG. 7;

FIG. 9 is an enlarged cross-sectional view of region IX of FIG. 8;

FIG. 10 is a plan view of a second layer arranged in a first island portion of a display device, according to an embodiment of the present disclosure;

FIG. 11 is a plan view of a portion of a display device according to an embodiment of the present disclosure;

FIG. 12 is a cross-sectional view taken along line XII-XII' of FIG. 10, illustrating a portion of a display device according to an embodiment of the present disclosure;

FIG. 13 is a cross-sectional view of a portion of a display device according to an embodiment of the present disclosure;

FIG. 14A is a schematic perspective view of an electronic apparatus including a display device, according to an embodiment of the present disclosure;

FIG. 14B is a schematic block diagram of an electronic apparatus including a display device, according to an embodiment of the present disclosure; and

FIGS. 15A-15I are each a schematic perspective view of an embodiment of an electronic apparatus including a display device, according to an embodiment of the present disclosure.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the example embodiments are described herein, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

As the present disclosure allows for various modifications and numerous embodiments, particular embodiments will be illustrated in the drawings and described in detail in the detailed description. Effects and features of the present disclosure and methods of achieving the same will become apparent by referring to embodiments described herein in detail with reference to the drawings. However, the present disclosure is not limited to the embodiments disclosed below and may be implemented in various forms.

Hereinafter, embodiments of the present disclosure will be described in detail with reference to the accompanying drawings, and in the description with reference to the drawings, the same or corresponding components are indicated by the same reference numerals and redundant descriptions thereof are omitted.

In the following embodiments, the terms "first," "second," etc. are not used in a limiting sense, but are used for the purpose of distinguishing one component from another component.

In the following embodiments, singular expressions include plural expressions unless the context clearly indicates otherwise.

In the following embodiments, the terms "include," "have," etc. specify the presence of features or components described in the specification, and do not preclude the possibility of addition of one or more other features or components.

The terms “about” or “approximately” as used herein are inclusive of the stated value and include a suitable range of deviation for the particular value as determined by one of ordinary skill in the art, considering the measurement in question and the error associated with measurement of the particular quantity. The terms “about” or “approximately” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

In the following embodiments, reference to a portion, such as a layer, a region, or a component, being on or above another portion includes not only the case where the portion is directly on the other portion, but also the case where intervening layers, regions, or components are present therebetween.

Sizes of components in the drawings may be exaggerated or reduced for convenience of description. For example, sizes and thicknesses of components in the drawings are arbitrarily illustrated for convenience of description, and thus, the present disclosure is not necessarily limited to the illustrations.

When a certain embodiment may be implemented differently, a specific process order may be performed differently from the described order. For example, two processes described in succession may be performed substantially simultaneously, or may be performed in an order opposite to the described order.

In the present specification, the expression "A and/or B" represents A, B, or A and B. In some aspects, the expression "at least one of A and B" represents A, B, or A and B.

In the following embodiments, reference to layers, regions, or components being connected to each other includes the case where the layers, regions, or components are directly connected to each other, and/or the case where the layers, regions, or components are indirectly connected to each other with intervening layers, regions, or components therebetween. For example, in the present specification, reference to layers, regions, or components being electrically connected to each other represents the case where the layers, regions, or components are directly electrically connected to each other, and/or the case where the layers, regions, or components are indirectly electrically connected to each other with intervening layers, regions, or components therebetween.

An x-axis, a y-axis, and a z-axis are not limited to three axes on a Cartesian coordinate system, and may be interpreted in a broad sense including the three axes. For example, the x-axis, the y-axis, and the z-axis may be perpendicular to one another, or may represent different directions that are not perpendicular to one another.

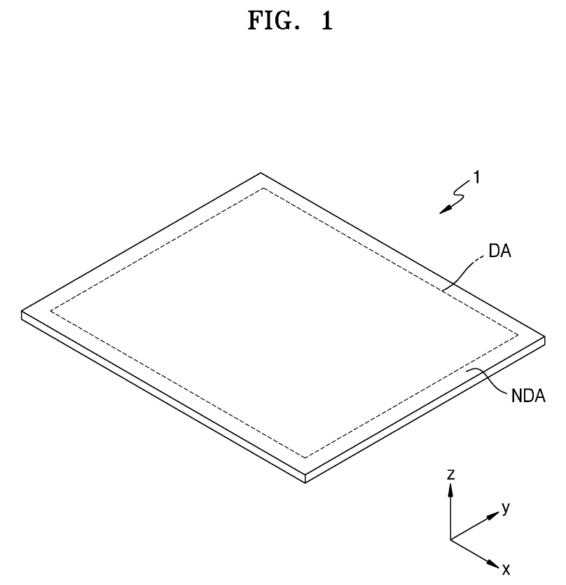

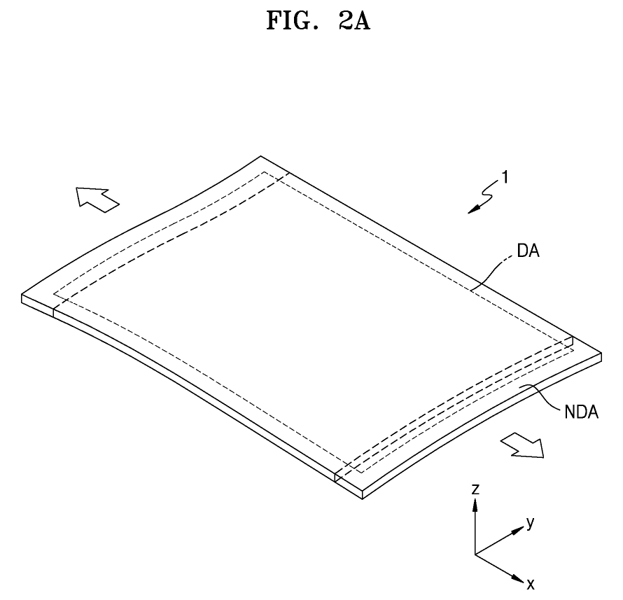

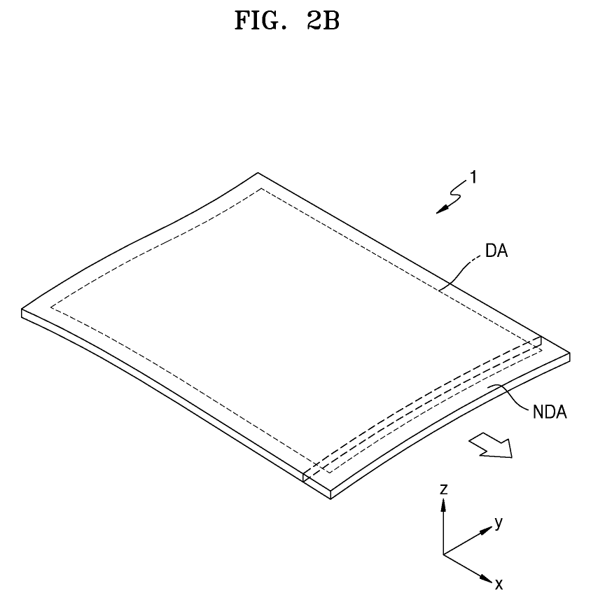

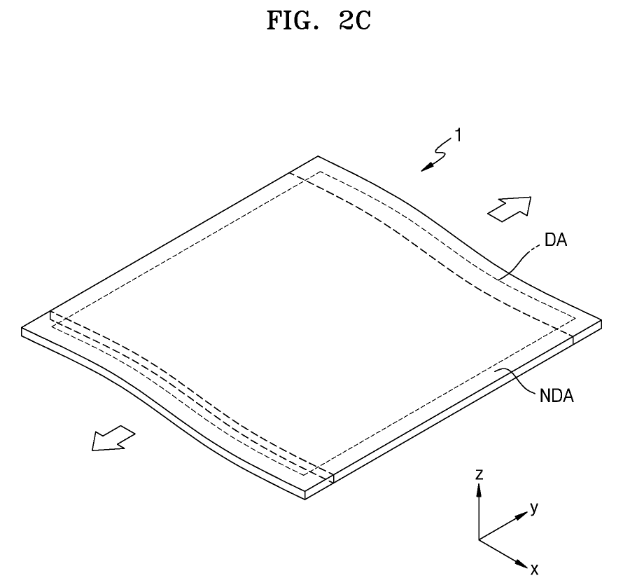

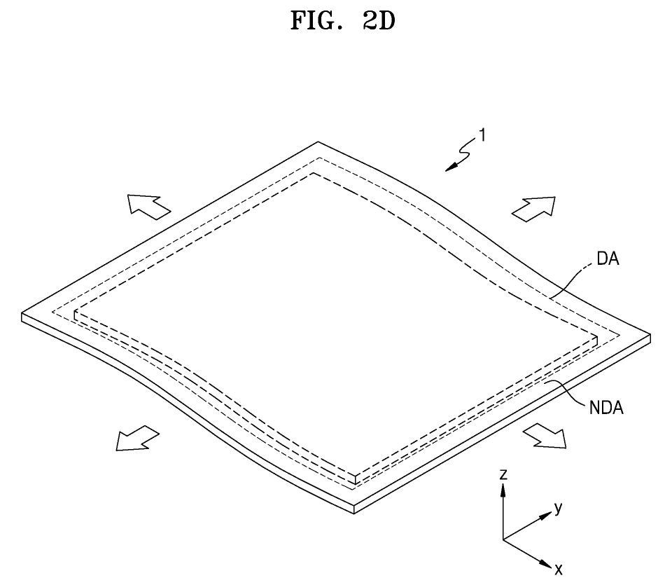

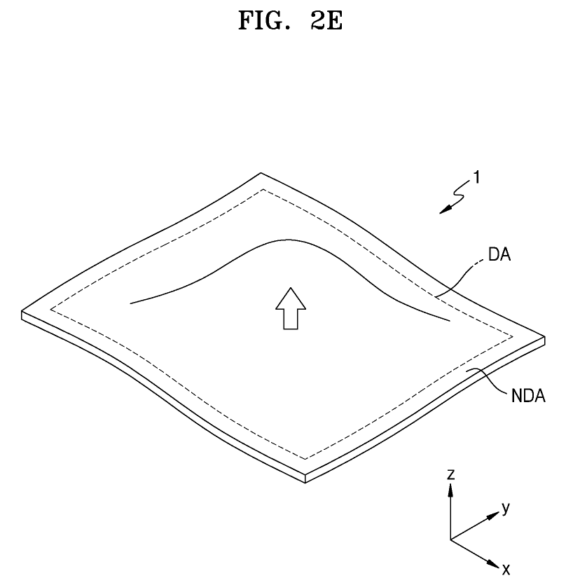

FIG. 1 is a schematic perspective view of a display device 1 according to an embodiment of the present disclosure. FIGS. 2A and 2B are perspective views of a state in which the display device 1 of FIG. 1 is stretched in a first direction. FIG. 2C is a perspective view of a state in which the display device 1 of FIG. 1 is stretched in a second direction. FIG. 2D is a perspective view of a state in which the display device of FIG. 1 is stretched in the first direction and the second direction. FIG. 2E is a perspective view of a state in which the display device 1 of FIG. 1 is stretched in a third direction.

Referring to FIG. 1, the display device 1 may include a display area DA and a non-display area NDA. The display area DA may include a plurality of pixels. The display device 1 may provide a certain image by using light emitted from the plurality of pixels. The non-display area NDA may be arranged outside the display area DA. The non-display area NDA may be an area in which pixels are not arranged, and may entirely surround the display area DA.

The display device 1 may be stretched in various directions and revert to its original shape (e.g. recover its initial form). The display device 1 may be stretched in a first direction (e.g., an x-direction and/or a -x-direction) due to an external force applied by an external object or a user. In an embodiment, as illustrated in FIGS. 2A and 2B, the display area DA and/or the non-display area NDA of the display device 1 may be stretched in the first direction (e.g., the x-direction and/or the -x-direction). For example, the display device 1 may be stretched in the x-direction and the -x-direction, as illustrated in FIG. 2A, or may be stretched in the x-direction with one side thereof fixed, as illustrated in FIG. 2B.

The display device 1 may be stretched in a second direction (e.g., a y-direction and/or a -y-direction) due to an external force applied by an external object or a user. In an embodiment, as illustrated in FIG. 2C, the display area DA and/or the non-display area NDA of the display device 1 may be stretched in the y-direction and the -y-direction. In another embodiment, the display device 1 may be stretched in the y-direction or the -y-direction with one side thereof fixed.

The display device 1 may be stretched in a plurality of directions, for example, in the first direction (e.g., the x-direction and/or the -x-direction) and the second direction (e.g., the y-direction and/or the -y-direction), due to an external force applied by an external object or a part of the human body. As illustrated in FIG. 2D, the display area DA and/or the non-display area NDA of the display device 1 may be stretched in the ±x-direction and the ±y-direction.

The display device 1 may be stretched in a third direction (e.g., a z-direction or a -z-direction) due to an external force applied by an external object or a part of the human body. In an embodiment, FIG. 2E illustrates that a portion of the display device 1, for example, a portion of the display area DA, protrudes in the z-direction. In another embodiment, a portion of the display device 1, for example, a portion of the display area DA, may protrude in the -z-direction (or be recessed in the z-direction).

FIGS. 2A-2E show that the display device 1 is stretched in the first direction, the second direction, and/or the third direction, but embodiments of the present disclosure are not limited thereto. In another embodiment, the display device 1 may be variously deformed into an irregular shape, for example, may be bent or twisted along two or more axes.

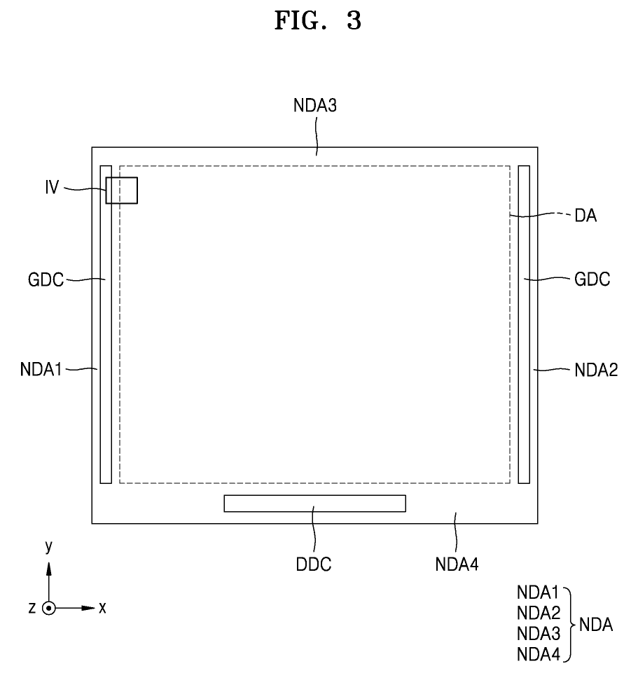

FIG. 3 is a schematic plan view of the display device 1 according to an embodiment of the present disclosure.

A plurality of pixels may be arranged in the display area DA of the display device 1. Each pixel may include sub-pixels that emit light of different colors. Light-emitting elements respectively corresponding to the sub-pixels may be arranged in the display area DA. In the non-display area NDA surrounding the display area DA, circuits for providing electrical signals to the light-emitting elements arranged in the display area DA and transistors electrically connected to the light-emitting elements may be located. A gate driving circuit GDC may be arranged in each of a first non-display area NDA1 and a second non-display area NDA2 that are arranged on two sides of the display area DA. The gate driving circuit GDC may include drivers for providing electrical signals to gate electrodes of the transistors electrically connected to the light-emitting elements. FIG. 3 illustrates that the gate driving circuit GDC is arranged in each of the first non-display area NDA1 and the second non-display area NDA2, but embodiments of the present disclosure are not limited thereto. In another embodiment, the gate driving circuit GDC may be arranged in one of the first non-display area NDA1 and the second non-display area NDA2.

A data driving circuit DDC may be arranged in a third non-display area NDA3 and/or a fourth non-display area NDA4 that connect the first non-display area NDA1 and the second non-display area NDA2 to each other. In an embodiment, FIG. 3 illustrates that the data driving circuit DDC is arranged in the fourth non-display area NDA4. In another embodiment, the data driving circuit DDC may be arranged in each of the third non-display area NDA3 and the fourth non-display area NDA4.

FIG. 3 illustrates that the data driving circuit DDC is arranged in the fourth non-display area NDA4 of the display device 1, but embodiments of the present disclosure are not limited thereto. In another embodiment, the display device 1 may further include a flexible circuit board (not illustrated) electrically connected thereto through a terminal portion (not illustrated) arranged in the fourth non-display area NDA4, and the data driving circuit DDC may be arranged on the above-described flexible circuit board.

In some embodiments, the elongation of the non-display area NDA may be equal to or less than the elongation of the display area DA. In an embodiment, the non-display area NDA may have a different elongation for each area. For example, the first non-display area NDA1, the second non-display area NDA2, and the third non-display area NDA3 may have substantially the same elongation, but the fourth non-display area NDA4 may have an elongation that is less than the elongation of each of the first non-display area NDA1, the second non-display area NDA2, and the third non-display area NDA3. In the present specification, the term "elongation" refers to a numerical value representing a change in length (ΔL/L) by which the display device 1 may be stretched without physical damage to the display device 1 when an external force is applied to the display device 1. Here, ΔL represents the amount of change in the length of the display device, and L represents the initial length of the display device.

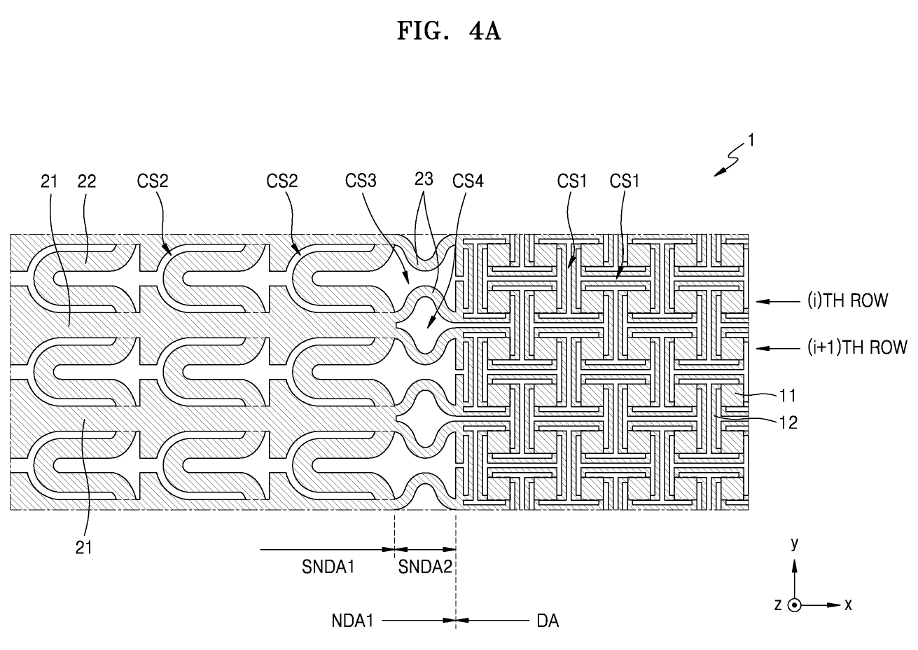

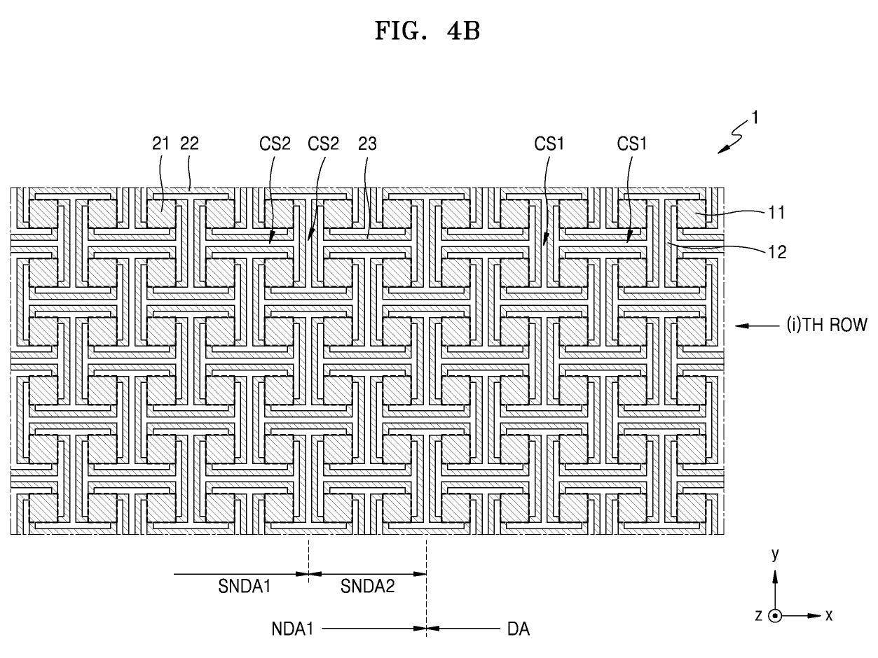

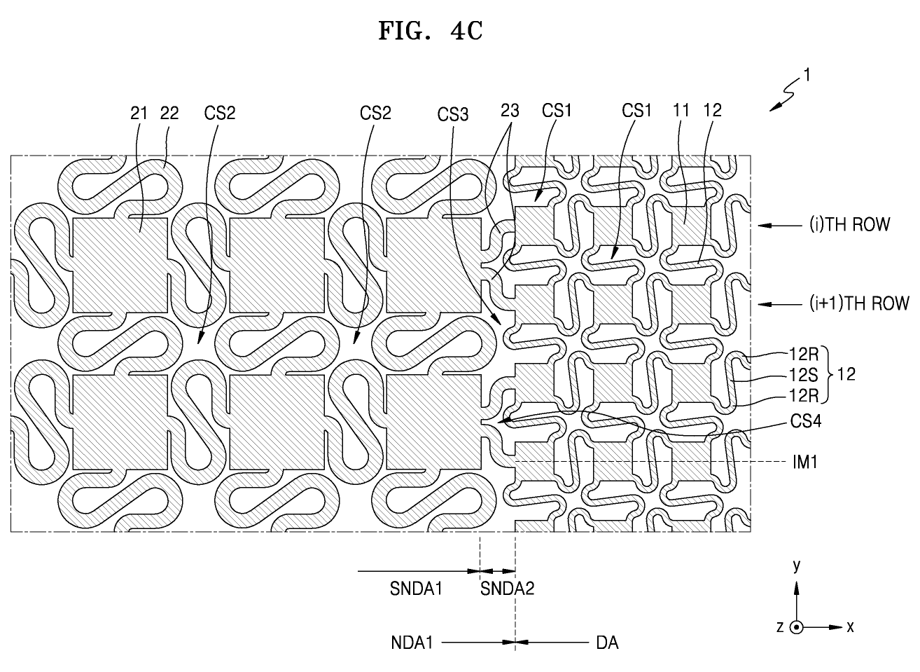

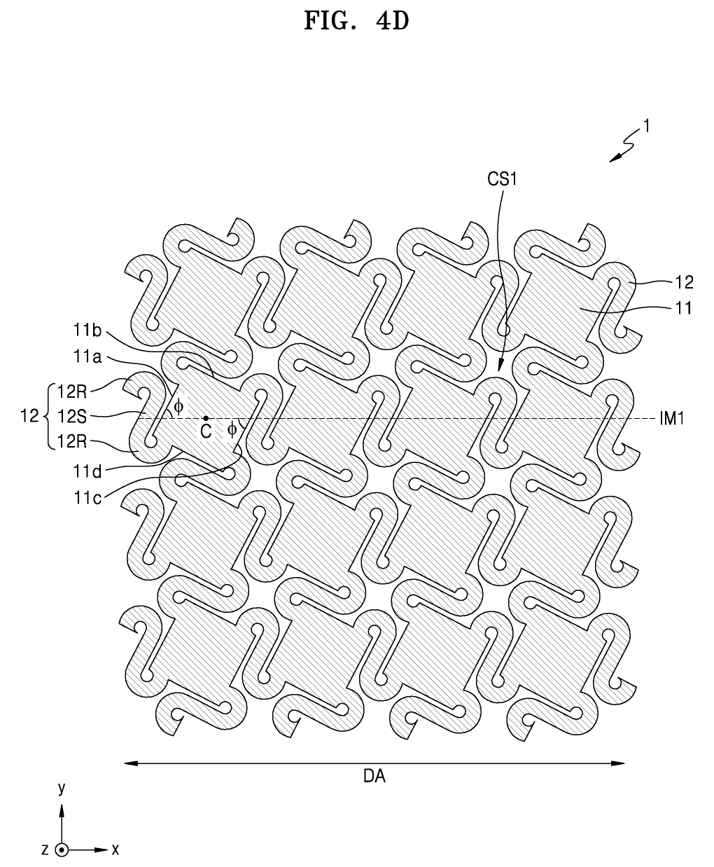

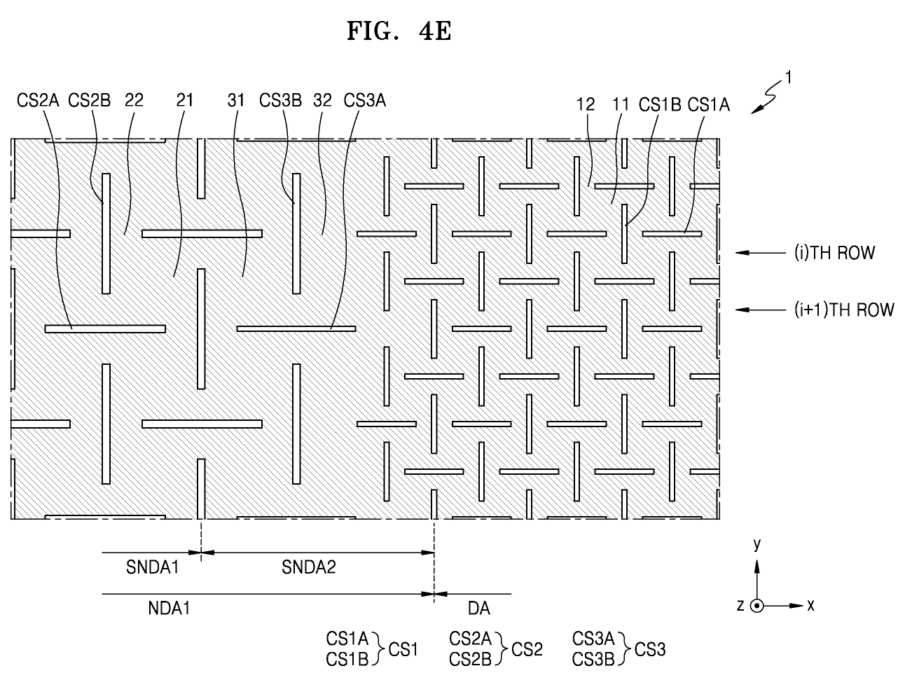

FIG. 4A is an enlarged plan view of region IV of FIG. 3 as a portion of the display device 1 according to an embodiment of the present disclosure.

Referring to FIG. 4A, the display device 1 may include, in the display area DA, first island portions 11 apart from each other in the first direction (e.g., the x-direction or the -x-direction) and the second direction (e.g., the y-direction or the -y-direction), and first bridge portions 12 connecting adjacent ones of the first island portions 11 to each other.

Each first island portion 11 may be connected to a plurality of first bridge portions 12. For example, each first island portion 11 may be connected to four first bridge portions 12. Two first bridge portions 12 may be arranged on two sides of the first island portion 11 in the first direction (e.g., the x-direction or the -x-direction), and the remaining two first bridge portions 12 may be arranged on two sides of the first island portion 11 in the second direction (e.g., the y-direction or the -y-direction). In an embodiment, the four first bridge portions 12 may be respectively connected to four sides of the first island portion 11. The four first bridge portions 12 may be respectively adjacent to corners of the first island portion 11.

The first bridge portions 12 may be apart from each other by a first opening portion CS1 located between the first bridge portions 12. In an embodiment, a first opening portion CS1 having an approximately H shape and a first opening portion CS1 having an approximately I shape, which is obtained by rotating the above-described H shape by 90 degrees, may be alternately and repeatedly arranged in the first direction (e.g., the x-direction or the -x-direction) and the second direction (e.g., the y-direction or the -y-direction). Two ends of each first bridge portion 12 may be respectively connected to adjacent ones of the first island portions 11, and one side of each first bridge portion 12 may be apart from one side of an adjacent one of the first island portions 11 and/or one side of another first bridge portion 12 by the first opening portion CS1.

The display device 1 may include, in a non-display area, for example, the first non-display area NDA1 illustrated in FIG. 4A, second island portions 21 apart from each other, and second bridge portions 22 connecting adjacent ones of the second island portions 21 to each other.

Each second island portion 21 may extend in the first direction (e.g., the x-direction or the -x-direction). The second island portions 21 may be apart from each other in the second direction (e.g., the y-direction or the -y-direction) crossing the first direction (e.g., the x-direction or the -x-direction). Each second island portion 21 may include the drivers of the gate driving circuit GDC (FIG. 3) described with reference to FIG. 3.

The second bridge portion 22 may have a serpentine shape. The length of the second bridge portion 22 may be greater than the shortest distance between adjacent ones of the second island portions 21 in the second direction (e.g., the y-direction or the -y-direction). In an embodiment, the second bridge portion 22 may have an approximately omega (Ω) shape that is convex toward the first direction (e.g., the x-direction or the -x-direction). The second bridge portions 22 may be arranged between adjacent ones of the second island portions 21, and may be apart from each other.

The second bridge portions 22 between adjacent ones of the second island portions 21 may be apart from each other by a second opening portion CS2. Between adjacent ones of the second island portions 21, second opening portions CS2 and second bridge portions 22 may be arranged alternately in the first direction (e.g., the x-direction or the -x-direction). The second opening portions CS2 may have the same shape. Two ends of each second bridge portion 22 may be connected to adjacent ones of the second island portions 21, and one side of each second bridge portion 22 may be apart from one side of an adjacent one of the second island portions 21 and/or one side of another second bridge portion 22 by the second opening portion CS2.

One second island portion 21 arranged in the first non-display area NDA1 may correspond to the first island portions 11 in a plurality of rows arranged in the display area DA. For example, one second island portion 21 arranged in the first non-display area NDA1 may correspond to the first island portions 11 arranged in an (i)th row and the first island portions 11 arranged in an (i+1)th row in the display area DA (where i is a positive integer greater than 0). FIG. 4A illustrates that one second island portion 21 corresponds to two rows of first island portions 11, but embodiments of the present disclosure are not limited thereto. In another embodiment, one second island portion 21 arranged in the first non-display area NDA1 may correspond to n rows of first island portions 11 arranged in the display area DA (where n is a positive integer greater than or equal to 3).

The non-display area, for example, the first non-display area NDA1, may include a first sub-non-display area SNDA1 in which the second island portions 21 and the second bridge portions 22 described herein are arranged, and a second sub-non-display area SNDA2 between the first sub-non-display area SNDA1 and the display area DA. Third bridge portions 23 may be arranged in the second sub-non-display area SNDA2 to connect the display area DA and the first sub-non-display area SNDA1 to each other. One end of the third bridge portion 23 may be connected to the second island portion 21 and/or the second bridge portion 22, and the other end of the third bridge portion 23 may be connected to the first island portion 11 and/or the first bridge portion 12.

The third bridge portion 23 may have a serpentine shape. In an embodiment, the shape of the third bridge portion 23 may be different from the shape of each of the first bridge portion 12 and the second bridge portion 22. In an embodiment, as illustrated in FIG. 4A, the third bridge portion 23 may have an approximately omega (Ω) shape that is convex toward the second direction (e.g., the y-direction or the -y-direction). Adjacent ones of the third bridge portions 23 arranged in the second direction (e.g., the y-direction or the -y-direction) may have structures symmetrical to each other, for example, one may be convex in the y-direction, and another one may be convex in the -y-direction. Between the third bridge portions 23, a structure in which a third opening portion CS3 and a fourth opening portion CS4 having different shapes are repeated may be provided. The width of the third bridge portion 23 may be different from the width of the first bridge portion 12 and the width of the second bridge portion 22. In an embodiment, the width of the third bridge portion 23 may be greater than the width of the first bridge portion 12 and less than the width of the second bridge portion 22.

FIG. 4A illustrates that the second island portion 21 and the second bridge portion 22 of the non-display area, for example, the first non-display area NDA1, have different shapes from the first island portion 11 and the first bridge portion 12 of the display area DA, respectively. In another embodiment of the present disclosure, the second island portion 21 and the second bridge portion 22 of the non-display area may have the same shapes as the first island portion 11 and the first bridge portion 12 of the display area DA, respectively.

FIG. 4B is an enlarged plan view of the region IV of FIG. 3 as a portion of the display device 1 according to an embodiment of the present disclosure.

Referring to FIG. 4B, the display device 1 includes, in the display area DA, first island portions 11 apart from each other, and first bridge portions 12 connecting adjacent ones of the first island portions 11, which are apart from each other by a first opening portion CS1, to each other. The structure of the display area DA of FIG. 4B may be the same as the structure of the display area DA described herein with reference to FIG. 4A.

The display device 1 may include second island portions 21 and second bridge portions 22 that are arranged in a non-display area, for example, the first non-display area NDA1. In an embodiment, the second island portions 21 and the second bridge portions 22 may have substantially the same shapes as the first island portions 11 and the first bridge portions 12, respectively.

The second island portions 21 may be apart from each other in the first direction (e.g., the x-direction or the -x-direction) and the second direction (e.g., the y-direction or the -y-direction) in the non-display area, for example, the first non-display area NDA1. Each of the second bridge portions 22 may connect adjacent ones of the second island portions 21 to each other. The second bridge portions 22 may be apart from each other by a second opening portion CS2 located between the second bridge portions 22.

The second opening portion CS2 may have substantially the same shape as the first opening portion CS1. For example, a second opening portion CS2 having an approximately H shape and a second opening portion CS2 having an approximately I shape may be alternately and repeatedly arranged in the non-display area, for example, the first non-display area NDA1. Two ends of each second bridge portion 22 may be respectively connected to adjacent ones of the second island portions 21, and one side of each second bridge portion 22 may be apart from one side of an adjacent one of the second island portions 21 and/or one side of another second bridge portion 22 by the second opening portion CS2.

Each second island portion 21 may be connected to four second bridge portions 22. Each second island portion 21 may include the drivers of the gate driving circuit GDC (FIG. 3) described with reference to FIG. 3.

The second island portions 21 in one row arranged in the first non-display area NDA1 may correspond to the first island portions 11 in one row arranged in the display area DA. For example, the second island portions 21 arranged in an (i)th row in the first direction (e.g., the x-direction or the -x-direction) in the first non-display area NDA1 may correspond to the first island portions 11 arranged in the same row, for example, the (i)th row, in the display area DA (where i is a positive integer greater than 0).

The display device 1 may include third bridge portions 23 arranged in a second sub-non-display area SNDA2 to connect the display area DA and a first sub-non-display area SNDA1 to each other. The non-display area, for example, the first non-display area NDA1, may include the first sub-non-display area SNDA1 in which the second island portions 21 and the second bridge portions 22 are arranged, and the second sub-non-display area SNDA2 including the third bridge portions 23 and located between the first sub-non-display area SNDA1 and the display area DA. The third bridge portion 23 may be substantially the same as the first bridge portion 12 and the second bridge portion 22. For example, the width of the third bridge portion 23 may be the same as the width of the first bridge portion 12 and the width of the second bridge portion 22.

FIG. 4C is an enlarged plan view of the region IV of FIG. 3 as a portion of a display device according to an embodiment of the present disclosure.

Referring to FIG. 4C, the display device 1 may include, in the display area DA, first island portions 11 apart from each other in the first direction (e.g., the x-direction or the -x-direction) and the second direction (e.g., the y-direction or the -y-direction), and first bridge portions 12 connecting adjacent ones of the first island portions 11 to each other.

The first bridge portions 12 may be arranged apart from each other by a first opening portion CS1 located between the first bridge portions 12. The first bridge portion 12 may have a serpentine shape. For example, as illustrated in FIG. 4C, the first bridge portion 12 may approximately have an S shape, for example, may include two round portions 12R and a straight portion 12S between the two round portions 12R.

Each first island portion 11 may be connected to a plurality of first bridge portions 12. For example, each first island portion 11 may be connected to four first bridge portions 12. Two first bridge portions 12 may be arranged on two sides of the first island portion 11 in the first direction (e.g., the x-direction or the -x-direction), and the remaining two first bridge portions 12 may be arranged on two sides of the first island portion 11 in the second direction (e.g., the y-direction or the -y-direction). The four first bridge portions 12 may be respectively connected to four sides of the first island portion 11. The four first bridge portions 12 may be respectively adjacent to corners of the first island portion 11.

The display device 1 may include, in a non-display area, for example, the first non-display area NDA1 illustrated in FIG. 4C, second island portions 21 apart from each other in the first direction (e.g., the x-direction or the -x-direction) and the second direction (e.g., the y-direction or the -y-direction), and second bridge portions 22 connecting adjacent ones of the second island portions 21 to each other.

The second bridge portions 22 may be arranged apart from each other by a second opening portion CS2 located between the second bridge portions 22. The second bridge portion 22 may have a serpentine shape. For example, as illustrated in FIG. 4C, the second bridge portion 22 may approximately have an S shape. The size and/or width of the second bridge portion 22 may be different from the size and/or width of the first bridge portion 12. For example, the size and/or width of the second bridge portion 22 may be greater than the size and/or width of the first bridge portion 12. The radius of curvature of a round portion of the second bridge portion 22 may be different from the radius of curvature of a round portion of the first bridge portion 12. For example, the radius of curvature of the round portion of the second bridge portion 22 may be greater than the radius of curvature of the round portion of the first bridge portion 12.

Each second island portion 21 may be connected to a plurality of second bridge portions 22. Each second island portion 21 may be connected to four second bridge portions 22. Two second bridge portions 22 may be arranged on two sides of the second island portion 21 in the first direction (e.g., the x-direction or the -x-direction), and the remaining two second bridge portions 22 may be arranged on two sides of the second island portion 21 in the second direction (e.g., the y-direction or the -y-direction). In an embodiment, the four second bridge portions 22 may be respectively connected to four sides of the second island portion 21. Each second bridge portion 22 may be connected to a central portion of each side of the second island portion 21.

The second island portions 21 in one row arranged in the first non-display area NDA1 may correspond to the first island portions 11 in a plurality of rows arranged in the display area DA. For example, the second island portions 21 in one row arranged in the first non-display area NDA1 may correspond to the first island portions 11 arranged in an (i)th row and the first island portions 11 arranged in an (i+1)th row in the display area DA (where i is a positive integer greater than 0). In another embodiment, the second island portions 21 in one row may correspond to n rows of first island portions 11 (where n is a positive integer greater than or equal to 3).

The non-display area, for example, the first non-display area NDA1, may include a first sub-non-display area SNDA1 in which the second island portions 21 and the second bridge portions 22 described herein are arranged, and a second sub-non-display area SNDA2 between the first sub-non-display area SNDA1 and the display area DA. Third bridge portions 23 may be arranged in the second sub-non-display area SNDA2 to connect the display area DA and the first sub-non-display area SNDA1 to each other. One end of the third bridge portion 23 may be connected to the second island portion 21, and the other end of the third bridge portion 23 may be connected to the first island portion 11. For example, one end of the third bridge portion 23 may be connected to a central portion of one side of the second island portion 21, and the other end of the third bridge portion 23 may be connected to a central portion of one side of the first island portion 11.

The third bridge portion 23 may have a serpentine shape. In an embodiment, the shape of the third bridge portion 23 may be different from the shape of each of the first bridge portion 12 and the second bridge portion 22. The width of the third bridge portion 23 may be different from the width of the first bridge portion 12 and the width of the second bridge portion 22. The width of the third bridge portion 23 may be greater than the width of the first bridge portion 12 and less than the width of the second bridge portion 22. A third opening portion CS3 and a fourth opening portion CS4 having different shapes may be alternately arranged between the third bridge portions 23 in the second direction (e.g., the y-direction or the -y-direction).

FIG. 4D is an enlarged plan view of the display area DA of FIG. 3 as a portion of the display device 1 according to an embodiment of the present disclosure.

Referring to FIG. 4D, the display device 1 may include, in the display area DA, first island portions 11 apart from each other in the first direction (e.g., the x-direction or the -x-direction) and the second direction (e.g., the y-direction or the -y-direction), and first bridge portions 12 connecting adjacent ones of the first island portions 11 to each other. The first bridge portions 12 may be arranged apart from each other by a first opening portion CS1 located between the first bridge portions 12.

In an embodiment, at least one of sides of the first island portion 11 may be oblique to an imaginary line connecting centers C of the first island portions 11 to each other in the first direction (e.g., the x-direction or the -x-direction) and/or the second direction (e.g., the y-direction or the -y-direction). In this regard, FIG. 4D illustrates that the first island portion 11 includes first to fourth sides 11a, 11b, 11c, and 11d, wherein the first to fourth sides 11a, 11b, 11c, and 11d extend in a direction oblique to a first imaginary line IM1 connecting the centers C of the first island portions 11 to each other. Although FIG. 4D illustrates that the first imaginary line IM1 extends in the first direction (e.g., the x-direction or the -x-direction), the first imaginary line IM1 may extend in the second direction (e.g., the y-direction or the -y-direction).

In an embodiment, the first side 11a and the third side 11c, which are parallel to each other, may intersect the first imaginary line IM1. Among angles formed by the first side 11a and the first imaginary line IM1, a smaller angle (hereinafter referred to as a minor angle φ) may be greater than 0 degrees and less than 90 degrees. A minor angle φ formed by the third side 11c and the first imaginary line IM1 may be greater than 0 degrees and less than 90 degrees.

The first island portion 11 may be connected to a plurality of first bridge portions 12. For example, the first island portion 11 may be connected to four first bridge portions 12. Two first bridge portions 12 may be arranged on two sides of the first island portion 11 in the first direction (e.g., the x-direction or the -x-direction), and the remaining two first bridge portions 12 may be arranged on two sides of the first island portion 11 in the second direction (e.g., the y-direction or the -y-direction).

The first bridge portion 12 may have a serpentine shape. For example, as illustrated in FIG. 4D, the first bridge portion 12 may approximately have an S shape, for example, may include two round portions 12R and a straight portion 12S between the two round portions 12R.

In an embodiment, the straight portion 12S may be substantially parallel to a side of an adjacent one of the first island portions 11, as illustrated in FIG. 4D. For example, the straight portions 12S of the first bridge portions 12 located on two sides of the first island portion 11 in the first direction (e.g., the x-direction or the -x-direction) may be substantially parallel to sides (e.g., the first side 11aand the third side 11c) of the first island portion 11. The straight portions 12S of the first bridge portions 12 located on two sides of the first island portion 11 in the second direction (e.g., the y-direction or the -y-direction) may be substantially parallel to sides (e.g., the second side 11band the fourth side 11d) of the first island portion 11.

Each of the first island portions 11 illustrated in FIG. 4D may be understood as each of the first island portions 11 illustrated in FIG. 4C being rotated by a first angle (e.g., an acute angle) with respect to the center C. Accordingly, at least one of the sides of the first island portion 11 may be oblique to the imaginary line connecting the centers C of the first island portions 11 to each other in the first direction (e.g., the x-direction or the -x-direction) and/or the second direction (e.g., the y-direction or the -y-direction). According to the arrangement of the first island portion 11 and/or the structure of the first bridge portion 12 described herein, the area of the first opening portion CS1 illustrated in FIG. 4D may be relatively smaller than the area of the first opening portion CS1 illustrated in FIG. 4C, and thus, the display device 1 according to the embodiment illustrated in FIG. 4D may provide a relatively high-resolution image.

FIG. 4D illustrates that the straight portion 12S of the first bridge portion 12 is substantially parallel to a side of the first island portion 11 adjacent to the straight portion 12S, but embodiments of the present disclosure are not limited thereto. In another embodiment, the straight portion 12S of the first bridge portion 12 may be oblique to a side of the first island portion 11 adjacent to the straight portion 12S, as illustrated in FIG. 4C.

In an embodiment, the structure of the first non-display area NDA1 (FIG. 3) of the display device 1, which is not disclosed in FIG. 4D, may be the same as the structure of the display area DA disclosed in FIG. 4D. In an embodiment, the structure of the first non-display area NDA1 (FIG. 3) of the display device 1, which is not disclosed in FIG. 4D, may be substantially the same as the structure of the display area DA disclosed in FIG. 4D, wherein the area of the second island portion arranged in the first non-display area NDA1 (FIG. 3) may be greater than the area of the first island portion 11. In this case, one second island portion may correspond to a plurality of first island portions 11 arranged in adjacent rows, as described with reference to FIG. 4C. In an embodiment, the structure of the first non-display area NDA1 (FIG. 3) of the display device 1, which is not disclosed in FIG. 4D, may be substantially the same as the structure of the first non-display area NDA1 illustrated in one of FIGS. 4A to 4C. As such, the structure of the first non-display area NDA1 (FIG. 3) may be variously selected within the range disclosed in the present specification.

FIG. 4E is an enlarged plan view of the region IV of FIG. 3 as a portion of a display device according to an embodiment of the present disclosure.

Referring to FIG. 4E, the display device 1 includes, in the display area DA, first island portions 11 apart from each other, and first bridge portions 12 connecting adjacent ones of the first island portions 11, which are apart from each other by a first opening portion CS1, to each other.

The first opening portion CS1 may have a bar shape. The first opening portion CS1 may include a first sub-opening portion CS1A extending in the first direction (e.g., the x-direction or the -x-direction), and a second sub-opening portion CS1B extending in the second direction (e.g., the y-direction or the -y-direction). The first sub-opening portion CS1A and the second sub-opening portion CS1B may each have a bar shape. The first sub-opening portion CS1A and the second sub-opening portion CS1B may have substantially the same width and length. The length of each of the first sub-opening portion CS1A and the second sub-opening portion CS1B represents a value measured along an extension direction, and the width thereof represents a value measured along a direction perpendicular to a length direction (e.g., the extension direction).

The display device 1 may include second island portions 21 and second bridge portions 22 that are arranged in a non-display area, for example, a first sub-non-display area SNDA1. The second island portions 21 may be apart from each other in the first sub-non-display area SNDA1 in the first direction (e.g., the x-direction or the -x-direction) and the second direction (e.g., the y-direction or the -y-direction). Each of the second bridge portions 22 may connect adjacent ones of the second island portions 21 to each other. The second bridge portions 22 may be apart from each other by a second opening portion CS2 located between the second bridge portions 22.

The second opening portion CS2 may have a bar shape. The second opening portion CS2 may include a first sub-opening portion CS2A extending in the first direction (e.g., the x-direction or the -x-direction), and a second sub-opening portion CS2B extending in the second direction (e.g., the y-direction or the -y-direction). The first sub-opening portion CS2A and the second sub-opening portion CS2B may each have a bar shape. The first sub-opening portion CS2A and the second sub-opening portion CS2B may have substantially the same width and length. Each second island portion 21 may be connected to four second bridge portions 22. Each second island portion 21 may include the drivers of the gate driving circuit GDC (FIG. 3) described with reference to FIG. 3. Some of the drivers of the gate driving circuit GDC (FIG. 3) may also be arranged in a second sub-non-display area SNDA2. For example, some third island portions 31 may include some drivers.

One second island portion 21 arranged in the first non-display area NDA1 may correspond to the first island portions 11 in a plurality of rows arranged in the display area DA. For example, one second island portion 21 arranged in the first non-display area NDA1 may correspond to the first island portions 11 arranged in an (i)th row and the first island portions 11 arranged in an (i+1)th row in the display area DA (where i is a positive integer greater than 0). FIG. 4E illustrates that one second island portion 21 corresponds to two rows of the first island portions 11, but embodiments of the present disclosure are not limited thereto. In another embodiment, one second island portion 21 arranged in the first non-display area NDA1 may correspond to n rows of first island portions 11 arranged in the display area DA (where n is a positive integer greater than or equal to 3).

The display device 1 may include third island portions 31 and third bridge portions 32 that are arranged in the second sub-non-display area SNDA2 to connect the display area DA and the first sub-non-display area SNDA1 to each other. Adjacent ones of the third island portions 31 may be apart from each other by a third opening portion CS3, and may be connected to each other by the third bridge portions 32.

The third opening portion CS3 may have a bar shape. The third opening portion CS3 may include a first sub-opening portion CS3A extending in the first direction (e.g., the x-direction or the -x-direction), and a second sub-opening portion CS3B extending in the second direction (e.g., the y-direction or the -y-direction). The first sub-opening portion CS3A and the second sub-opening portion CS3B may each have a bar shape. The first sub-opening portion CS3A and the second sub-opening portion CS3B may have different widths and/or lengths.

In an embodiment, the length of the first sub-opening portion CS3A of the third opening portion CS3 in the first direction (e.g., the x-direction or the -x-direction) may be equal to or greater than the length of the second sub-opening portion CS3B of the third opening portion CS3 in the second direction (e.g., the y-direction or the -y-direction). The width of the first sub-opening portion CS3A of the third opening portion CS3 in the second direction (e.g., the y-direction or the -y-direction) may be less than the width of the second sub-opening portion CS3B of the third opening portion CS3 in the first direction (e.g., the x-direction or the -x-direction).

In an embodiment, the length of the first sub-opening portion CS3A of the third opening portion CS3 in the first direction (e.g., the x-direction or the -x-direction) may be equal to the length of the first sub-opening portion CS2A of the second opening portion CS2 in the first direction (e.g., the x-direction or the -x-direction), and may be greater than the length of the first sub-opening portion CS1A of the first opening portion CS1 in the first direction (e.g., the x-direction or the -x-direction). The width of the first sub-opening portion CS3A of the third opening portion CS3 in the second direction (e.g., the y-direction or the -y-direction) may be less than the width of the first sub-opening portion CS2A of the second opening portion CS2 in the second direction (e.g., the y-direction or the -y-direction), and may be equal to the width of the first sub-opening portion CS1A of the first opening portion CS1 in the second direction (e.g., the y-direction or the -y-direction).

In an embodiment, the length of the second sub-opening portion CS3B of the third opening portion CS3 in the second direction (e.g., the y-direction or the -y-direction) may be equal to the length of the second sub-opening portion CS2B of the second opening portion CS2 in the second direction (e.g., the y-direction or the -y-direction), and may be greater than the length of the second sub-opening portion CS1B of the first opening portion CS1 in the second direction (e.g., the y-direction or the -y-direction). The width of the second sub-opening portion CS3B of the third opening portion CS3 in the first direction (e.g., the x-direction or the -x-direction) may be equal to the width of the second sub-opening portion CS2B of the second opening portion CS2 in the first direction (e.g., the x-direction or the -x-direction), and may be greater than the width of the second sub-opening portion CS1B of the first opening portion CS1 in the first direction (e.g., the x-direction or the -x-direction).

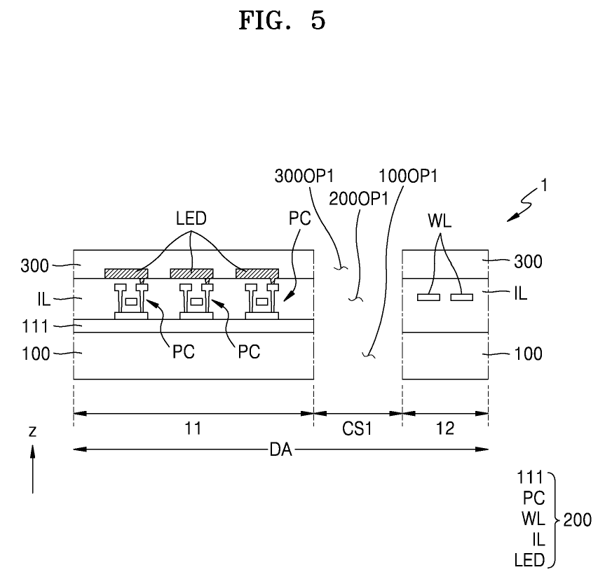

FIG. 5 is a schematic cross-sectional view of the first island portion 11 and the first bridge portion 12 that are arranged in the display area DA of the display device 1, according to an embodiment of the present disclosure.

Referring to FIG. 5, the first island portion 11 and the first bridge portion 12 arranged in the display area DA may be apart from each other with the first opening portion CS1 therebetween. The first island portion 11 may include light-emitting elements LED and circuits, for example, pixel driving circuit units (or pixel driving circuits) PC, electrically connected thereto to drive the light-emitting elements, and the first bridge portion 12 may include wirings WL electrically connected to the pixel driving circuit units PC respectively arranged in adjacent ones of the first island portions 11.

In the first island portion 11, a buffer layer 111 including an inorganic insulating material may be arranged on a substrate 100, and the pixel driving circuit unit PC may be arranged on the buffer layer 111. An insulating layer IL including an inorganic insulating material and/or an organic insulating material may be arranged between the pixel driving circuit unit PC and the light-emitting element LED. The light-emitting element LED may be arranged on the insulating layer IL, and may be electrically connected to a corresponding one of the pixel driving circuit units PC. The light-emitting elements LED may emit light of different colors or light of the same color. In an embodiment, the light-emitting elements LED may emit red light, green light, and blue light, respectively. In some embodiments, the light-emitting elements LED may emit white light. In another embodiment, the light-emitting elements LED may emit red light, green light, blue light, and white light, respectively.

The substrate 100 may include polymer resin, such as polyethersulfone, polyarylate, polyether imide, polyethylene naphthalate, polyethylene terephthalate, polyphenylene sulfide, polyimide, polycarbonate, cellulose triacetate, or cellulose acetate propionate. In an embodiment, the substrate 100 may be a single layer including the above-described polymer resin. In another embodiment, the substrate 100 may have a multi-layer structure including a base layer including the above-described polymer resin and a barrier layer including an inorganic insulating material. The substrate 100 including the polymer resin may be flexible, rollable, or bendable.

In an embodiment, FIG. 5 illustrates three pixel driving circuit units PC arranged in each first island portion 11 and three light-emitting elements LED respectively connected to the pixel driving circuit units PC, but embodiments of the present disclosure are not limited thereto. In another embodiment, the number of pixel driving circuit units PC and light-emitting elements LED arranged in the first island portion 11 may be one, two, or four or more.

An encapsulation layer 300 may be arranged on the light-emitting element LED, and may protect the light-emitting element LED from an external force and/or moisture penetration. The encapsulation layer 300 may include an inorganic encapsulation layer and/or an organic encapsulation layer. In some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. In another embodiment, the encapsulation layer 300 may include an organic material such as resin. In some embodiments, the encapsulation layer 300 may include urethane epoxy acrylate. The encapsulation layer 300 may include a photosensitive material such as photoresist.

In the first bridge portion 12, an insulating layer IL including an organic insulating material may be arranged on a substrate 100. In an example in which the display device 1 is stretched, the first bridge portion 12, which is subject to relatively high deformation, may not have a layer including an inorganic insulating material that is prone to cracking, unlike the first island portion 11.

In an embodiment, the substrate 100 corresponding to the first bridge portion 12 may have the same stacked structure as the substrate 100 corresponding to the first island portion 11. In an embodiment, the substrate 100 corresponding to the first bridge portion 12 and the substrate 100 corresponding to the first island portion 11 may be polymer resin layers formed together in the same process. In another embodiment, the substrate 100 corresponding to the first bridge portion 12 may have a different stacked structure from the substrate 100 corresponding to the first island portion 11. In some embodiments, the substrate 100 corresponding to the first island portion 11 may have a multi-layer structure including a base layer including polymer resin and a barrier layer including an inorganic insulating material, and the substrate 100 corresponding to the first bridge portion 12 may have a structure including a polymer resin layer without a layer including an inorganic insulating material.

As described herein, the wirings WL of the first bridge portion 12 may be signal lines (e.g.. gate lines, data lines, etc.) for providing electrical signals to transistors included in the pixel driving circuit unit PC of the first island portion 11, or may be voltage lines (e.g., driving voltage lines, initialization voltage lines, etc.) for providing voltage to the same. An encapsulation layer 300 may also be arranged in the first bridge portion 12. In another embodiment, the encapsulation layer 300 may not be present in the first bridge portion 12.

Referring to FIGS. 4A-4E and 5, the substrate 100 corresponding to the first island portion 11 and the substrate 100 corresponding to the first bridge portion 12 may be connected to each other. In other words, the plan views illustrated in FIGS. 4A-4E may be substantially the same as the plan view of the substrate 100 in FIG. 5. In other words, the substrate 100 may include an area corresponding to the first island portion 11, an area corresponding to the first bridge portion 12, and an opening 100OP1 having the same shape as the first opening portion CS1.

Similarly, the encapsulation layer 300 corresponding to the first island portion 11 and the encapsulation layer 300 corresponding to the first bridge portion 12 may be connected to each other. For example, the plan views illustrated in FIGS. 4A-4E may be substantially the same as the plan view of the encapsulation layer 300. In other words, the encapsulation layer 300 may include an area corresponding to the first island portion 11, an area corresponding to the first bridge portion 12, and an opening 300OP1 having the same shape as the first opening portion CS1.

A circuit-light-emitting element layer 200 between the substrate 100 and the encapsulation layer 300 may include the buffer layer 111, the pixel driving circuit unit PC, the wiring WL, the insulating layer IL, and the light-emitting element LED. Similar to the substrate 100, the plan views illustrated in FIGS. 4A-4E may be substantially the same as the plan view of the circuit-light-emitting element layer 200. In other words, the circuit-light-emitting element layer 200 may include an opening 200OP1 having the same shape as the first opening portion CS1.

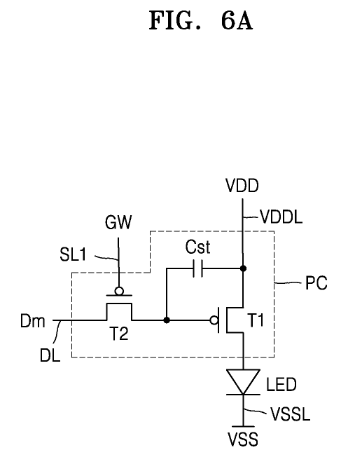

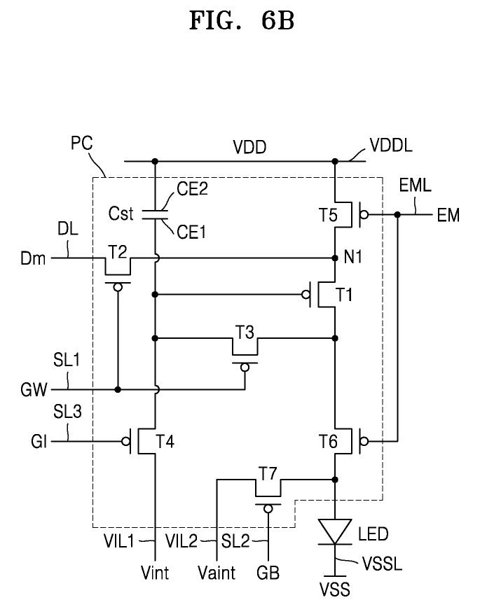

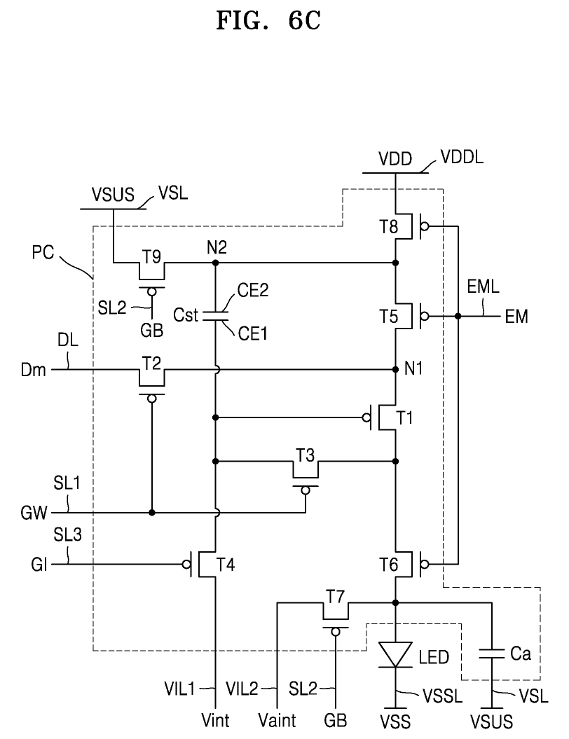

FIGS. 6A-6C are each an equivalent circuit diagram of a sub-pixel of the display device 1 according to an embodiment of the present disclosure.

Referring to FIG. 6A, the light-emitting element LED corresponding to the sub-pixel may be electrically connected to the pixel driving circuit unit PC, and the pixel driving circuit unit PC may include a first transistor T1, a second transistor T2, and a storage capacitor Cst. The pixel driving circuit unit PC may be electrically connected to a signal line and a voltage line. The signal line may include a gate line, such as a first scan line SL1, and a data line DL, and the voltage line may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 may be configured to transmit, to the first transistor T1, a data signal Dm input from the data line DL, in response to the first scan signal GW input from the first scan line SL1.

The storage capacitor Cst may be electrically connected to the second transistor T2 and the first voltage line VDDL, and may store a voltage corresponding to the difference between a voltage received from the second transistor T2 and a first power voltage VDD supplied by the first voltage line VDDL.

The first transistor T1 may be a driving transistor, and may control a driving current flowing through the light-emitting element LED. The first transistor T1 may be connected to the first voltage line VDDL and the storage capacitor Cst. The first transistor T1 may control a driving current flowing from the first voltage line VDDL to the light-emitting element LED, in response to a voltage value stored in the storage capacitor Cst. The light-emitting element LED may emit light having a certain luminance according to the driving current. A first electrode of the light-emitting element LED may be electrically connected to the first transistor T1, and a second electrode of the light-emitting element LED may be electrically connected to a second voltage line VSSL configured to supply a second power voltage VSS.

Although FIG. 6A illustrates that the pixel driving circuit unit PC includes two transistors and one storage capacitor, in another embodiment, the pixel driving circuit unit PC may include three or more transistors.

Referring to FIG. 6B, the pixel driving circuit unit PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit unit PC is electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit, to the pixel driving circuit unit PC, a first initialization voltage Vint for initializing the first transistor T1. The second initialization voltage line VIL2 may be configured to transmit, to the pixel driving circuit unit PC, a second initialization voltage Vaint for initializing a first electrode of the light-emitting element LED.

The first transistor T1 may be electrically connected to the first voltage line VDDL via the fifth transistor T5, and may be electrically connected to the light-emitting element LED via the sixth transistor T6. The first transistor T1 serves as a driving transistor, receives a data signal Dm according to a switching operation of the second transistor T2, and supplies a driving current to the light-emitting element LED.

The second transistor T2 is a data writing transistor, and is electrically connected to the first scan line SL1 and the data line DL. The second transistor T2 is electrically connected to the first voltage line VDDL via the fifth transistor T5. The second transistor T2 is turned on in response to a first scan signal GW received through the first scan line SL1 to perform a switching operation of transmitting, to a first node N1, the data signal Dm transmitted through the data line DL.

The third transistor T3 is electrically connected to the first scan line SL1, and is electrically connected to the light-emitting element LED via the sixth transistor T6. The third transistor T3 may be turned on in response to the first scan signal GW received through the first scan line SL1 to diode-connect the first transistor T1.

The fourth transistor T4 is a first initialization transistor, and is electrically connected to the third scan line SL3 and the first initialization voltage line VIL1. The fourth transistor T4 is turned on in response to a third scan signal GI received through the third scan line SL3, and is configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of another pixel driving circuit unit arranged in a previous row of the pixel driving circuit unit PC.

The fifth transistor T5 may be an operation control transistor, and the sixth transistor T6 may be an emission control transistor. The fifth transistor T5 and the sixth transistor T6 are electrically connected to the emission control line EML, and are simultaneously turned on in response to an emission control signal EM received through the emission control line EML to form a current path such that a driving current flows from the first voltage line VDDL to the light-emitting element LED.

The seventh transistor T7 may be a second initialization transistor, and may be electrically connected to the second scan line SL2, the second initialization voltage line VIL2, and the sixth transistor T6. The seventh transistor T7 may be turned on in response to a second scan signal GB received through the second scan line SL2, and may be configured to transmit the second initialization voltage Vaint from the second initialization voltage line VIL2 to the first electrode of the light-emitting element LED to initialize the first electrode of the light-emitting element LED.

The storage capacitor Cst includes a first electrode CE1 and a second electrode CE2. The first electrode CE1 is electrically connected to the gate electrode of the first transistor T1, and the second electrode CE2 is electrically connected to the first voltage line VDDL. The storage capacitor Cst may store and maintain a voltage corresponding to the difference between voltages of the first voltage line VDDL and the gate electrode of the first transistor T1, thereby maintaining a voltage applied to the gate electrode of the first transistor T1.

Referring to FIG. 6C, the pixel driving circuit unit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit unit PC is electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2, a sustain voltage line VSL, and a first voltage line VDDL.

The first voltage line VDDL may be configured to transmit a first power voltage VDD to the first transistor T1. The first initialization voltage line VIL1 may be configured to transmit, to the pixel driving circuit unit PC, a first initialization voltage Vint for initializing the first transistor T1. The second initialization voltage line VIL2 may be configured to transmit, to the pixel driving circuit unit PC, a second initialization voltage Vaint for initializing a first electrode of the light-emitting element LED. The sustain voltage line VSL may be configured to provide a sustain voltage VSUS to a second node N2, for example, a second electrode CE2 of the storage capacitor Cst, during an initialization section and a data writing section.

The first transistor T1 may be electrically connected to the first voltage line VDDL via the fifth transistor T5 and the eighth transistor T8, and may be electrically connected to the light-emitting element LED via the sixth transistor T6. The first transistor T1 may serve as a driving transistor, may receive a data signal Dm according to a switching operation of the second transistor T2, and may supply a driving current to the light-emitting element LED.

The second transistor T2 is electrically connected to the first scan line SL1 and the data line DL, and is electrically connected to the first voltage line VDDL via the fifth transistor T5 and the eighth transistor T8. The second transistor T2 is turned on in response to a first scan signal GW received through the first scan line SL1 to perform a switching operation of transmitting, to a first node N1, the data signal Dm transmitted through the data line DL.

The third transistor T3 is electrically connected to the first scan line SL1, and is electrically connected to the light-emitting element LED via the sixth transistor T6. The third transistor T3 may be turned on in response to the first scan signal GW received through the first scan line SL1 to diode-connect the first transistor T1, thereby compensating for a threshold voltage of the first transistor T1.

The fourth transistor T4 is electrically connected to the third scan line SL3 and the first initialization voltage line VIL1, is turned on in response to a third scan signal GI received through the third scan line SL3, and is configured to transmit the first initialization voltage Vint from the first initialization voltage line VIL1 to the gate electrode of the first transistor T1 to initialize a voltage of the gate electrode of the first transistor T1. The third scan signal GI may correspond to a first scan signal of another pixel driving circuit unit arranged in a previous row of the pixel driving circuit unit PC.

The fifth transistor T5, the sixth transistor T6, and the eighth transistor T8 are electrically connected to the emission control line EML, and are simultaneously turned on in response to an emission control signal EM received through the emission control line EML to form a current path such that a driving current flows from the first voltage line VDDL to the light-emitting element LED.

The seventh transistor T7 may be a second initialization transistor, and may be electrically connected to the second scan line SL2, the second initialization voltage line VIL2, and the sixth transistor T6. The seventh transistor T7 is turned on in response to a second scan signal GB received through the second scan line SL2, and is configured to transmit the second initialization voltage Vaint from the second initialization voltage line VIL2 to the first electrode of the light-emitting element LED to initialize the first electrode of the light-emitting element LED.

The ninth transistor T9 may be electrically connected to the second scan line SL2, the second electrode CE2 of the storage capacitor Cst, and the sustain voltage line VSL. The ninth transistor T9 may be turned on in response to the second scan signal GB received through the second scan line SL2, and may be configured to transmit the sustain voltage VSUS to the second node N2, for example, the second electrode CE2 of the storage capacitor Cst, during an initialization section and a data writing section.

The eighth transistor T8 and the ninth transistor T9 may each be electrically connected to the second node N2, for example, the second electrode CE2 of the storage capacitor Cst. In some embodiments, during an initialization section and a data writing section, the eighth transistor T8 may be turned off and the ninth transistor T9 may be turned on, and during an emission section, the eighth transistor T8 may be turned on and the ninth transistor T9 may be turned off. Because the sustain voltage VSUS is transmitted to the second node N2 during the initialization section and the data writing section, the uniformity (e.g., long range uniformity (LRU)) in luminance of the display device according to a voltage drop of the first voltage line VDDL may be improved.

The storage capacitor Cst includes a first electrode CE1 and the second electrode CE2. The first electrode CE1 is electrically connected to the gate electrode of the first transistor T1, and the second electrode CE2 is electrically connected to the eighth transistor T8 and the ninth transistor T9.

The auxiliary capacitor Ca may be electrically connected to the sixth transistor T6, the sustain voltage line VSL, and the first electrode of the light-emitting element LED. The auxiliary capacitor Ca may store and maintain a voltage corresponding to the difference between voltages of the first electrode of the light-emitting element LED and the sustain voltage line VSL while the seventh transistor T7 and the ninth transistor T9 are turned on, thereby preventing an increase in black luminance when the sixth transistor T6 is turned off.

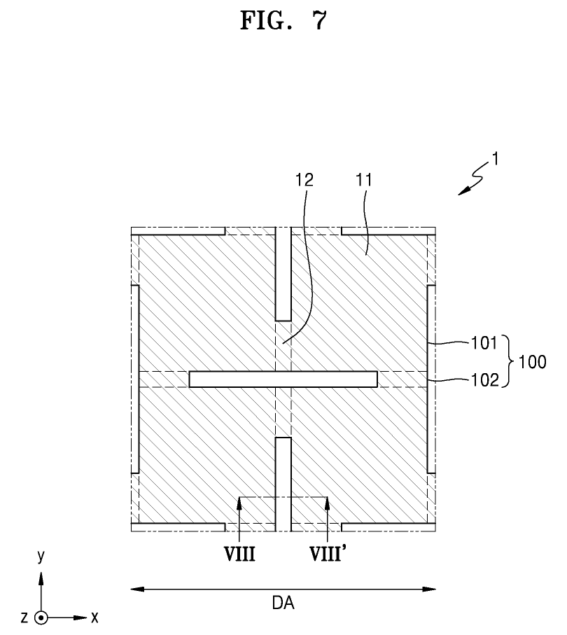

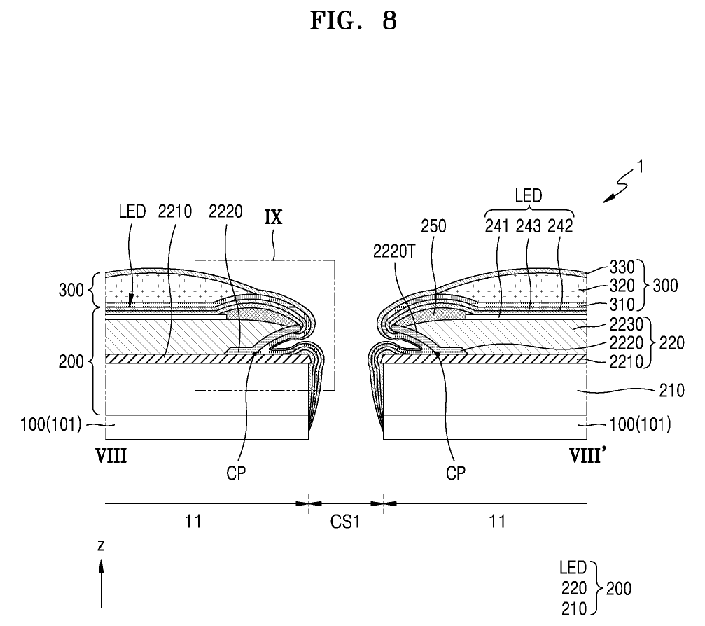

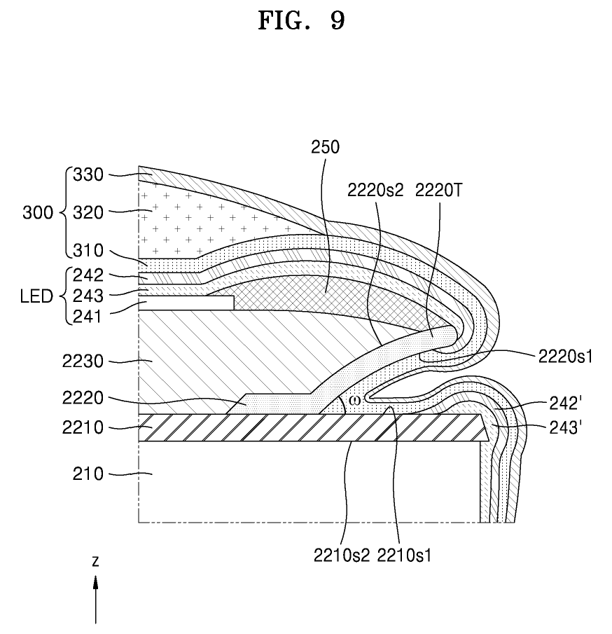

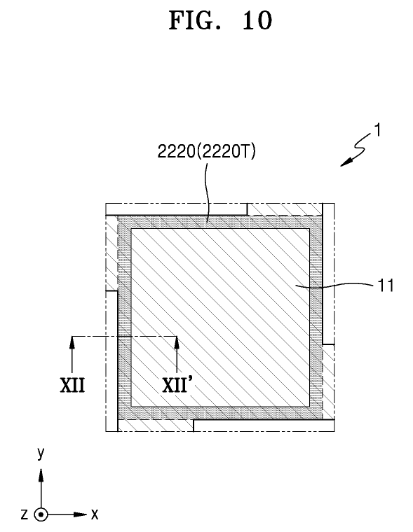

FIG. 7 is a plan view of a portion of the display device 1 according to an embodiment of the present disclosure, FIG. 8 illustrates a cross-section taken along line VIII-VIII' of FIGS. 7 and 9 is an enlarged cross-sectional view of region IX of FIG. 8. FIG. 10 is a plan view of a second layer 2220 arranged in the first island portion 11 of the display device 1, according to an embodiment of the present disclosure.

Referring to FIG. 7, the first island portion 11 of the display device 1 may be connected to a plurality of first bridge portions 12. For example, each first island portion 11 may be connected to four first bridge portions 12. Each of the first bridge portions 12 may connect two adjacent first island portions 11, which are apart from each other by the first opening portion CS1, to each other. As described herein with reference to FIG. 5, light-emitting elements LED (FIG. 5) and pixel driving circuit units PC (FIG. 5) electrically connected to the light-emitting elements LED may be arranged in the first island portion 11.

The display device 1 may include a substrate 100, a circuit-light-emitting element layer 200 arranged on the substrate 100, and an encapsulation layer 300, as illustrated in FIG. 8. Referring to FIGS. 7 and 8, the substrate 100 may include a first portion 101 corresponding to the first island portion 11 and a second portion 102 corresponding to the first bridge portion 12. The first portion 101 and the second portion 102 of the substrate 100 may be connected to each other as a single body.

The planar shape of the display device 1 illustrated in FIG. 7 may be substantially the same as the planar shape of the substrate 100. For example, the substrate 100 may include a first portion 101 corresponding to the first island portion 11 of the display device 1, and a second portion 102 corresponding to the first bridge portion 12 of the display device 1. In the present specification, the wording "first island portion 11 of the display device 1" may be used interchangeably with the wording "first portion 101 of the substrate 100," and the wording "first bridge portion 12 of the display device 1" may be used interchangeably with the wording "second portion 102 of the substrate 100." For example, the wording "A is arranged in the first island portion 11 of the display device 1" may indicate that "A is arranged on the first portion 101 of the substrate 100." For example, the wording "A is arranged in or extends to the first bridge portion 12 of the display device 1" may indicate that "A is arranged on or extends to the second portion 102 of the substrate 100."

As described herein, the substrate 100 may include the first portion 101 and the second portion 102. The first portion 101 and the second portion 102 may be connected to each other as a single body. The substrate 100 may include various materials, such as metal or polymer resin. In an embodiment, the substrate 100 may include a flexible material.

The circuit-light-emitting element layer 200 may include a circuit layer 210, a light-emitting element LED arranged on the circuit layer 210, and an upper structure layer 220 arranged between the circuit layer 210 and the light-emitting element LED. Although FIG. 8 illustrates one light-emitting element LED, two or more light-emitting elements LED may be arranged in the first island portion 11 (or the first portion 101 of the substrate 100).

The circuit layer 210 may include the pixel driving circuit unit PC (FIGS. 5 and 6A-6C) described with reference to FIGS. 5 and 6A-6C and insulating layers. The upper structure layer 220 may include three layers. The upper structure layer 220 may include a first layer 2210, a second layer 2220 arranged on the first layer 2210 and extending upward with respect to a first surface 2210s1 (FIG. 9, e.g., an upper surface) of the first layer 2210, and a third layer 2230 arranged on the second layer 2220.

The first layer 2210 may be an inorganic insulating layer including an inorganic insulating material including silicon oxide, silicon nitride, and/or silicon oxynitride. In an embodiment, the first layer 2210 may include a different material (e.g., a material having a different etching selectivity) from the uppermost layer among the layers included in the circuit layer 210. Accordingly, an edge of the first layer 2210, for example, a side surface of the first layer 2210, may protrude further in a lateral direction than a side surface of the uppermost layer among the layers included in the circuit layer 210 arranged below the first layer 2210, as illustrated in FIGS. 8 and 9.

Referring to FIGS. 8 and 9, the second layer 2220 may be arranged on the first layer 2210. A portion (e.g., a first portion) of the second layer 2220 may be in direct contact with the first surface 2210s1 (e.g., the upper surface) of the first layer 2210. A second surface 2210s2 of the first layer 2210, which is opposite to the first surface 2210s1 of the first layer 2210, may be in direct contact with the uppermost layer of the circuit layer 210.

The second layer 2220 may include a first surface (e.g., a lower surface) 2220s1 facing the first layer 2210 and a second surface (e.g., an upper surface) 2220s2 opposite to the first surface 2220s1. A portion of the first surface 2220s1, which corresponds to the portion (e.g., the first portion) of the second layer 2220, may be in direct contact with the first surface 2210s1 of the first layer 2210.

The second layer 2220 may extend in a direction away from the first surface 2210s1 (e.g., the upper surface) of the first layer 2210 (e.g., upward). A portion (e.g., a second portion, hereinafter referred to as an eaves portion 2220T) of the second layer 2220 may extend upward such that a space (or a gap) is present between the eaves portion 2220T of the second layer 2220 and the first layer 2210. The eaves portion 2220T of the second layer 2220 may form an overhang structure on the first surface (e.g., the upper surface) of the first layer 2210. An angle between the second layer 2220 and the first layer 2210, for example, a first angle ω between the first surface 2220s1 of the second layer 2220 and the first surface 2210s1 of the first layer 2210, may be an acute angle. In an embodiment, the first angle ω may be greater than 0 degrees and less than or equal to 40 degrees.

Referring to FIG. 10, the second layer 2220 may have a frame shape extending along an edge of the first island portion 11 in a plan view (or when viewed in a direction perpendicular to the substrate 100 (FIG. 8)). The second layer 2220 having a frame shape in a plan view may indicate that the eaves portion 2220T of the second layer 2220 has a frame shape in a plan view.

The second layer 2220 may include an inorganic material. Here, the inorganic material refers to a material that does not include carbon, and the second layer 2220 may include an insulating inorganic material or a conductive inorganic material. In an embodiment, the second layer 2220 may include an inorganic insulating material, such as silicon oxide, silicon nitride, and/or silicon oxynitride. In an embodiment, the second layer 2220 may include a conductive material. For example, the second layer 2220 may include a conductive material, including molybdenum (Mo), aluminum (Al), copper (Cu), titanium (Ti), etc., and may include a multi-layer or a single layer including the above-described material. The second layer 2220 may include a conductive oxide such as indium tin oxide (ITO).

When the second layer 2220 includes a conductive material, the second layer 2220 may have a constant voltage level. For example, the second layer 2220 may have the same voltage level as the second voltage line VSSL (FIGS. 6A-6C) described with reference to FIGS. 6A-6C. In an embodiment, the second layer 2220 may be electrically connected to the second voltage line VSSL (FIGS. 6A-6C), or the second layer 2220 may correspond to a portion of the second voltage line VSSL (FIGS. 6A-6C).

The third layer 2230 may be arranged on the second layer 2220, as illustrated in FIGS. 8 and 9. The third layer 2230 may overlap the second layer 2220 and the first layer 2210. The third layer 2230 may include a single organic insulating layer including an organic insulating material. The third layer 2230 may have a multi-layer structure including a layer including an organic insulating material and a layer including an inorganic insulating material.

The light-emitting element LED may be arranged on the third layer 2230. The light-emitting element LED may include a first electrode 241, a second electrode 242 on the first electrode 241, and an intermediate layer 243 between the first electrode 241 and the second electrode 242.

The first electrode 241 may be electrically connected to the transistors included in the circuit layer 210. The first electrode 241 may include a transparent conductive oxide, such as indium tin oxide (ITO), indium zinc oxide (IZO), zinc oxide (ZnO), indium oxide (In₂O₃), indium gallium oxide (IGO), or aluminum zinc oxide (AZO). In another embodiment, the first electrode 241 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the first electrode 241 may further include a layer including ITO, IZO, ZnO, or In₂O₃, on/below the above-described reflective layer. For example, the first electrode 241 may have a three-layer structure in which an ITO layer, a silver (Ag) layer, and an ITO layer are stacked.

A bank layer 250 may cover an edge of the first electrode 241, and may include an opening overlapping a portion of the first electrode 241. The bank layer 250 may include an insulating material. The bank layer 250 may include an organic insulating material such as polyimide. Alternatively, the bank layer 250 may include an inorganic insulating material. The bank layer 250 may include a colored material.

The intermediate layer 243 may include an emission layer overlapping the first electrode 241, and a functional layer. The emission layer may include an organic light-emitting material, such as a polymer or low-molecular weight organic material emitting light of a certain color. The emission layer may include an inorganic light-emitting material or quantum dots. The functional layer may include an electron transport layer, an electron injection layer, a hole transport layer, and/or a hole injection layer.

The second electrode 242 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof.

At least one of the layers (hereinafter, referred to as sub-layers) included in the intermediate layer 243 (e.g., the functional layer) and the second electrode 242 may be formed to entirely cover the first island portion 11. In a process of forming at least one sub-layer included in the intermediate layer 243, due to the eaves structure of the second layer 2220, a material forming the at least one sub-layer described herein may also be deposited on the first layer 2210 to form a first residue layer 243'. Similarly, in a process of forming the second electrode 242, a material forming the second electrode 242 may also be deposited on the first layer 2210 to form a second residue layer 242'.

The first residue layer 243' may include the same material as the at least one sub-layer included in the intermediate layer 243, and may be separate and apart from the at least one sub-layer included in the intermediate layer 243. The second residue layer 242' may include the same material as the second electrode 242, and may be separate and apart from the second electrode 242.

As illustrated in FIG. 8, the second electrode 242 may be formed to overlap the first island portion 11, and may pass over the bank layer 250 and be in direct contact with the eaves portion 2220T of the second layer 2220. As illustrated in FIG. 9, the second electrode 242 may be in direct contact with a portion of the first surface 2220s1 of the second layer 2220. For example, the second electrode 242 may be in direct contact with the eaves portion 2220T of the second layer 2220.

In an embodiment, the second layer 2220 may include a conductive material, and may have the same voltage level as the second voltage line VSSL (FIGS. 6A-6C), as described herein. In another embodiment, when the second layer 2220 includes an inorganic insulating material, the second electrode 242 may be electrically connected to the second voltage line included in the circuit layer 210.

The encapsulation layer 300 may be arranged on the light-emitting element LED. The encapsulation layer 300 may include an inorganic encapsulation layer. The encapsulation layer 300 may include an inorganic encapsulation layer and an organic encapsulation layer. In an embodiment, FIGS. 8 and 9 show that the encapsulation layer 300 includes a first inorganic encapsulation layer 310, an organic encapsulation layer 320 on the first inorganic encapsulation layer 310, and a second inorganic encapsulation layer 330 on the organic encapsulation layer 320.

The first inorganic encapsulation layer 310 may be arranged on the light-emitting element LED. The first inorganic encapsulation layer 310 may extend continuously toward the first surface 2210s1 of the first layer 2210 through the eaves structure of the second layer 2220. In this regard, FIG. 9 illustrates that the first inorganic encapsulation layer 310 extends continuously toward the first surface 2220s1 of the second layer 2220 and the first surface 2210s1 of the first layer 2210, which faces the first surface 2220s1 of the second layer 2220. The first inorganic encapsulation layer 310 may be in direct contact with the first surface 2220s1 of the second layer 2220 and the first surface 2210s1 of the first layer 2210. The first inorganic encapsulation layer 310 may cover a contact area between the second electrode 242 and the second layer 2220 (e.g., a contact area between the second electrode 242 and a portion of the first surface 2220s1 of the second layer 2220 illustrated in FIG. 9). The first inorganic encapsulation layer 310 may include aluminum oxide, tantalum oxide, hafnium oxide, zinc oxide, silicon oxide, silicon nitride, or/and silicon oxynitride.

The organic encapsulation layer 320 may be arranged between the first inorganic encapsulation layer 310 and the second inorganic encapsulation layer 330. An edge of the organic encapsulation layer 320 may be located on the bank layer 250. The organic encapsulation layer 320 may include a polymer-based material. The polymer-based material may include acrylic resin, epoxy-based resin, polyimide, polyethylene, etc. The acrylic resin may include, for example, polymethyl methacrylate, polyacrylic acid, etc.

The second inorganic encapsulation layer 330 may be arranged on the organic encapsulation layer 320. Like the first inorganic encapsulation layer 310, the second inorganic encapsulation layer 330 may extend continuously toward the first surface 2210s1 of the first layer 2210 through the eaves structure of the second layer 2220. In this regard, FIG. 9 illustrates that the second inorganic encapsulation layer 330 extends continuously toward the first surface 2220s1 of the second layer 2220 and the first surface 2210s1 of the first layer 2210, which faces the first surface 2220s1 of the second layer 2220. The second inorganic encapsulation layer 330 may cover a contact area between the second electrode 242 and the second layer 2220 (e.g., a contact area between the second electrode 242 and a portion of the first surface 2220s1 of the second layer 2220 illustrated in FIG. 9). The second inorganic encapsulation layer 330 may be in direct contact with the first inorganic encapsulation layer 310 on the first surface 2220s1 of the second layer 2220 and the first surface 2210s1 of the first layer 2210. The second inorganic encapsulation layer 330 may include aluminum oxide, tantalum oxide, hafnium oxide, zinc oxide, silicon oxide, silicon nitride, or/and silicon oxynitride.

In a space between the first layer 2210 and the eaves portion 2220T of the second layer 2220, as the first layer 2210, the eaves portion 2220T of the second layer 2220, and the first inorganic encapsulation layer 310 may be in contact with each other, thereby preventing external impurities (e.g., moisture) from penetrating toward the light-emitting element LED. The above-described effect of preventing moisture penetration may be further improved through a contact structure in which, in the space between the first layer 2210 and the eaves portion 2220T of the second layer 2220, the second inorganic encapsulation layer 330 is in direct contact with the first inorganic encapsulation layer 310.

The contact structure of the first inorganic encapsulation layer 310 and the second inorganic encapsulation layer 330 may extend onto a side surface of the circuit layer 210 and be in direct contact with the side surface of the circuit layer 210, and may extend onto a side surface of the substrate 100 (e.g., the first portion 101 of the substrate 100) and be in direct contact with the side surface of the substrate 100.

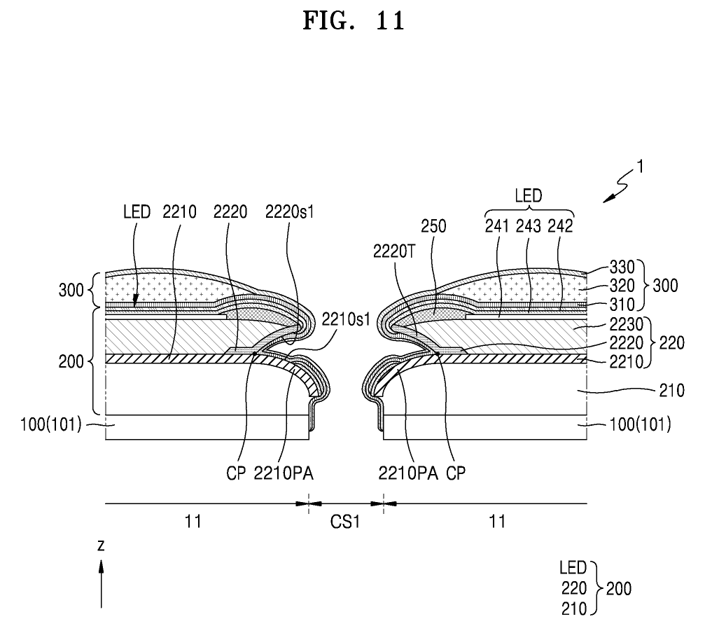

FIG. 11 is a plan view of a portion of the display device 1 according to an embodiment of the present disclosure.

The embodiment of the display device 1 illustrated in FIG. 11 includes all features of the embodiments described herein with reference to FIGS. 8-10, but differs therefrom in the shape of an edge of the first layer 2210. Descriptions of the same structures of the components illustrated in FIG. 11 are substituted with descriptions provided above with reference to FIGS. 8-10, and the differences are mainly described herein.

In an embodiment, the first layer 2210 may be substantially parallel to an upper surface of the substrate 100, as illustrated in FIG. 8. In another embodiment, a peripheral portion 2210PA of the first layer 2210 may extend away from the second layer 2220 (e.g., downward), as illustrated in FIG. 11.

In FIGS. 8 and 11, the first layer 2210 and the second layer 2220 may be in direct contact with each other, and may extend away from each other toward a side (edge) of the first island portion 11 from a first point CP where the contact between the first layer 2210 and the second layer 2220 ends. As illustrated in FIGS. 8 and 11, the second layer 2220 may extend upward from the first point CP, and the first layer 2210 may extend downward. In an embodiment, a portion (e.g., an edge portion or a peripheral portion 2220PA) of the second layer 2220 may extend downward from the first point CP, as illustrated in FIG. 11. In a direction from the first point CP toward the side (edge) of the first island portion 11, a gap between the first layer 2210 and the second layer 2220 may gradually increase, and in the case of the embodiment illustrated in FIG. 11, the area of contact with the first inorganic encapsulation layer 310 may be relatively increased, and/or the thickness of the first inorganic encapsulation layer 310 may be relatively large.

The first inorganic encapsulation layer 310 may be in direct contact with the first surface 2220s1 of the second layer 2220 and the first surface 2210s1 of the first layer 2210, as illustrated in FIG. 11. As illustrated in FIG. 11, when the first layer 2210 extends downward, a contact structure of the first inorganic encapsulation layer 310, the second layer 2220, and the first layer 2210 may be formed while the thickness of the first inorganic encapsulation layer 310 is maintained relatively large.

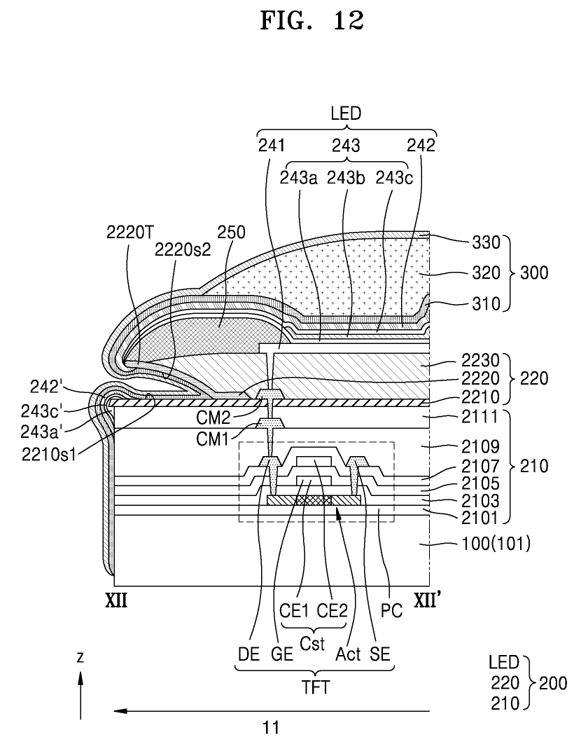

FIG. 12 is a cross-sectional view taken along line XII-XII' of FIG. 10, illustrating a portion of the display device 1 according to an embodiment of the present disclosure.

The circuit layer 210 may be arranged on the substrate 100, for example, the first portion 101 of the substrate 100, and may include a pixel driving circuit unit PC. The pixel driving circuit unit PC may include the transistors and capacitor(s) as illustrated in FIGS. 6A-6C, and in this regard, FIG. 12 illustrates one transistor TFT. The transistor TFT of FIG. 12 may correspond to the first transistor of FIG. 6A, but embodiments of the present disclosure are not limited thereto. The transistor TFT of FIG. 12 may correspond to the sixth transistor illustrated in FIGS. 6B and 6C.

A buffer layer 2101 may be arranged on the substrate 100, for example, on the first portion 101 of the substrate 100. The buffer layer 2101 may include an inorganic insulating material, such as silicon oxide, silicon nitride, or/and silicon oxynitride.

The transistor TFT may be arranged on the buffer layer 2101. The transistor TFT may include a semiconductor layer Act, a gate electrode GE, a source electrode SE, and a drain electrode DE.

The semiconductor layer Act may include polysilicon, amorphous silicon, an oxide semiconductor, an organic semiconductor, etc. The gate electrode GE may overlap the semiconductor layer Act with a gate insulating layer 2103 therebetween. The gate electrode GE may include a low-resistance metal material. The gate electrode GE may include a conductive material, including molybdenum (Mo), aluminum (Al), copper (Cu), titanium (Ti), etc., and may include a multi-layer or a single layer including the above-described material. The gate insulating layer 2103 may include an inorganic insulating material, such as silicon oxide, silicon nitride, or/and silicon oxynitride.

The source electrode SE and/or the drain electrode DE may be located on a second interlayer insulating layer 2107. The source electrode SE and/or the drain electrode DE may include a material having good conductivity. The source electrode SE and/or the drain electrode DE may include a conductive material, including molybdenum (Mo), aluminum (Al), copper (Cu), titanium (Ti), etc., and may include a multi-layer or a single layer including the above-described material. In an embodiment, the source electrode SE and/or the drain electrode DE may be formed in a multi-layer structure including a titanium layer, an aluminum layer, and a titanium layer (Ti/Al/Ti). The second interlayer insulating layer 2107 may include an inorganic insulating material, such as silicon oxide, silicon nitride, or/and silicon oxynitride.

The storage capacitor Cst may include a first electrode CE1 and a second electrode CE2 that overlap each other with a first interlayer insulating layer 2105 therebetween. The first interlayer insulating layer 2105 may include an inorganic insulating material, such as silicon oxide, silicon nitride, or/and silicon oxynitride.

The storage capacitor Cst may overlap the transistor TFT. In this regard, FIG. 12 illustrates that the gate electrode GE of the transistor TFT is the first electrode CE1 of the storage capacitor Cst. In another embodiment, the storage capacitor Cst may not overlap the transistor TFT. The storage capacitor Cst may be covered by the second interlayer insulating layer 2107. The second electrode CE2 of the storage capacitor Cst may include a conductive material, including molybdenum (Mo), aluminum (Al), copper (Cu), titanium (Ti), etc., and may include a multi-layer or a single layer including the above-described material.

A first insulating layer 2109 and a second insulating layer 2111 may be arranged on the pixel driving circuit unit PC. The first insulating layer 2109 and the second insulating layer 2111 may include an organic insulating material. A first connection piece CM1 may be arranged on the first insulating layer 2109, and may be electrically connected to the transistor TFT. A second connection piece CM2 may be arranged on the second insulating layer 2111 (e.g., on the second insulating layer 2111 and the first layer 2210), and may be electrically connected to the first connection piece CM1. FIG. 12 illustrates that the first electrode 241 of the light-emitting element LED is electrically connected to the transistor TFT through the first connection piece CM1 and the second connection piece CM2, but embodiments of the present disclosure are not limited thereto. In another embodiment, one of the first connection piece CM1 and the second connection piece CM2 may be omitted, and in this case, one of the first insulating layer 2109 and the second insulating layer 2111 may also be omitted. In another embodiment, the first electrode 241 of the light-emitting element LED and the transistor TFT may be electrically connected to each other through three or more connection pieces.

The upper structure layer 220 is arranged on the circuit layer 210. The first layer 2210 may be arranged on the uppermost layer of the circuit layer 210, for example, the second insulating layer 2111. As described herein with reference to FIGS. 8 and 9, the first layer 2210 may protrude further in a lateral direction than a side surface of the second insulating layer 2111.

The second layer 2220 may be arranged on the first layer 2210, and may extend upward. The specific structure of a portion of the second layer 2220, for example, the eaves portion 2220T, is the same as described herein with reference to FIGS. 8-10. The second layer 2220 may include an inorganic insulating material or a conductive material (e.g., a metallic material).

The third layer 2230 may be arranged on the second layer 2220, and may cover the eaves portion 2220T of the second layer 2220. The third layer 2230 may provide a relatively flat upper surface, and thus, the first electrode 241 of the light-emitting element LED may have a uniform thickness and a flat shape.

The first electrode 241 of the light-emitting element LED may be electrically connected to the second connection piece CM2 through a contact hole defined in the third layer 2230. The second connection piece CM2 may be electrically connected to the first connection piece CM1 through a contact hole penetrating the first layer 2210 and the second insulating layer 2111. The first connection piece CM1 may be electrically connected to the transistor TFT through a contact hole penetrating the first insulating layer 2109.

The bank layer 250 covers an edge of the first electrode 241 of the light-emitting element LED, and includes an opening overlapping a portion of the first electrode 241.

The intermediate layer 243 may include an emission layer 243boverlapping the first electrode 241. The intermediate layer 243 may further include a functional layer between the first electrode 241 and the second electrode 242. In this regard, FIG. 12 illustrates that the intermediate layer 243 includes a first functional layer 243a and a second functional layer 243c that are arranged between the first electrode 241 and the second electrode 242. The first functional layer 243a and the second functional layer 243c may be respectively arranged below and on the emission layer 243b.

The first functional layer 243a may be arranged between the first electrode 241 and the emission layer 243b. The first functional layer 243a may include a hole transport layer and/or a hole injection layer. The second functional layer 243cmay be arranged between the emission layer 243b and the second electrode 242. The second functional layer 243c may include an electron transport layer and/or an electron injection layer.

The second electrode 242 is arranged on the intermediate layer 243. The second electrode 242 may be in direct contact with the second layer 2220. The second electrode 242 may be in direct contact with a portion of a lower surface (e.g., a surface facing an upper surface of the first layer 2210) of the eaves portion 2220T.

A plurality of light-emitting elements LED may be arranged in the first island portion 11. In this case, the first electrodes 241 corresponding to the light-emitting elements LED may be arranged apart from each other. The emission layers 243bcorresponding to the light-emitting elements LED may include different materials depending on a color of light emitted from a corresponding one of the light-emitting elements LED, and may be apart from each other. Unlike the first electrodes 241, the first functional layer 243a, the second functional layer 243c, and the second electrode 242 may be shared by the plurality of light-emitting elements LED arranged in the first island portion 11.

The first functional layer 243a, the second functional layer 243c, and the second electrode 242 may be formed through a deposition process. Each of the first functional layer 243a, the second functional layer 243c, and the second electrode 242 may have an area that may substantially and entirely cover the first island portion 11.

In some embodiments, a material forming each of the first functional layer 243a, the second functional layer 243c, and the second electrode 242 may also be formed below the eaves portion 2220T. In this regard, FIG. 12 illustrates a first-1 residue layer 243a', a first-2 residue layer 243c', and a second residue layer 242' that are formed on an edge of the first layer 2210. At least one selected from the first-1 residue layer 243a' and the first-2 residue layer 243c' may correspond to the first residue layer 243' described herein with reference to FIG. 9.

As described herein with reference to FIGS. 8 and 9, because the second layer 2220 having an eaves structure is located in the first island portion 11, the first functional layer 243a, the second functional layer 243c, and the second electrode 242 may be separate and apart from the first-1 residue layer 243a', the first-2 residue layer 243c', and the second residue layer 242', respectively.

As described with reference to FIGS. 8 and 9, the first inorganic encapsulation layer 310 may extend and be in direct contact with the first surface 2220s1 of the second layer 2220 and the first surface 2210s1 of the first layer 2210, and may further extend onto a side surface of the circuit layer 210 and a side surface of the first portion 101 of the substrate 100. The second inorganic encapsulation layer 330 may also extend onto the first surface 2220s1 of the second layer 2220 and the first surface 2210s1 of the first layer 2210 and be in direct contact with the first inorganic encapsulation layer 310. The second inorganic encapsulation layer 330 may further extend onto the side surface of the circuit layer 210 and the side surface of the first portion 101 of the substrate 100.

Although FIG. 12 illustrates that the first layer 2210 is substantially parallel to the substrate 100, in another embodiment, the first layer 2210 may extend downward, as described herein with reference to FIG. 11.

FIGS. 8, 9, 11, and 12 show that the eaves portion 2220T is located inside an imaginary line (e.g., an imaginary line extending in the z-direction) passing through the side surface of the substrate 100 and/or the circuit layer 210. In this case, it is possible to prevent the eaves portion 2220T from breaking, and/or to sufficiently secure the contact structure of the first inorganic encapsulation layer 310 and the thickness of the first inorganic encapsulation layer 310 below the eaves portion 2220T. However, the present disclosure is not limited to the embodiments described herein. In another embodiment, the eaves portion 2220T may be located on an imaginary line (e.g., an imaginary line extending in the z-direction) passing through the side surface of the substrate 100 and/or the circuit layer 210, or may protrude outward (e.g., in a direction away from the center of the first island portion 11) through the above-described imaginary line.

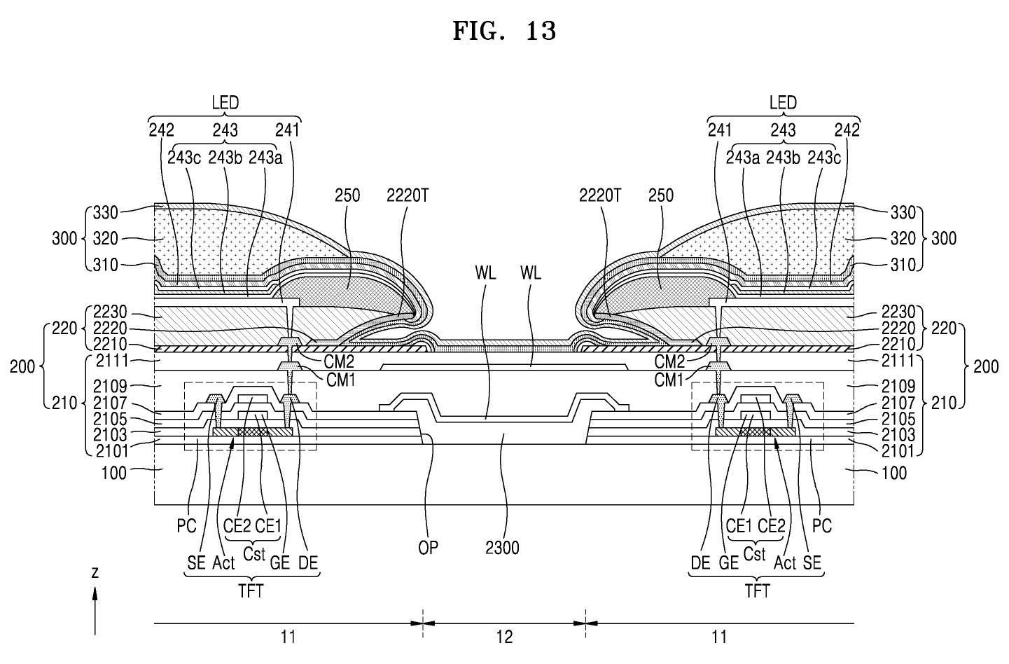

FIG. 13 is a cross-sectional view of a portion of the display device 1 according to an embodiment of the present disclosure, illustrating the structure of two adjacent first island portions and a first bridge portion therebetween. The structure of the first island portion 11 illustrated in FIG. 13 is the same as that in the embodiment described herein with reference to FIG. 12. Accordingly, descriptions of the structure of the first island portion 11 are substituted with descriptions provided above with reference to FIG. 12, etc., and the structure of the first bridge portion 12 is mainly described herein.

The inorganic insulating layers of the circuit layer 210, such as the buffer layer 2101, the gate insulating layer 2103, the first interlayer insulating layer 2105, and the second interlayer insulating layer 2107, may be removed from the first bridge portion 12. Each of the inorganic insulating layers of the circuit layer 210, such as the buffer layer 2101, the gate insulating layer 2103, the first interlayer insulating layer 2105, and the second interlayer insulating layer 2107, may include an opening OP located in the first bridge portion 12. In other words, the inorganic insulating layers, such as the buffer layer 2101, the gate insulating layer 2103, the first interlayer insulating layer 2105, and the second interlayer insulating layer 2107, arranged in one first island portion 11 may be apart from the inorganic insulating layers, such as the buffer layer 2101, the gate insulating layer 2103, the first interlayer insulating layer 2105, and the second interlayer insulating layer 2107, arranged in another first island portion 11.

In an embodiment, an organic layer 2300 may be arranged in the openings OP of the above-described inorganic insulating layers. The organic layer 2300 may include an organic insulating material.

The organic insulating layers of the circuit layer 210, such as the first insulating layer 2109 and the second insulating layer 2111, may extend from the first island portion 11 toward the first bridge portion 12.

The wirings WL respectively electrically connected to the pixel driving circuit unit PC of one first island portion 11 and the pixel driving circuit unit PC of another first island portion 11 may pass through (or extend across) the first bridge portion 12. The wirings WL may include signal lines (e.g., a scan line and a data line) and voltage lines (an initialization voltage line, a first voltage line, a second voltage line, etc.) described herein with reference to FIGS. 6A-6C.

Although FIG. 13 illustrates that the organic layer 2300 is arranged between the substrate 100 and the first insulating layer 2109 in the first bridge portion 12, in another embodiment, the organic layer 2300 may be omitted.

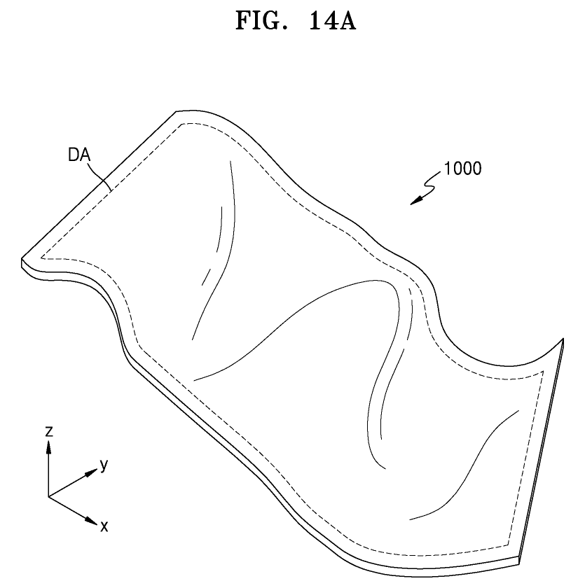

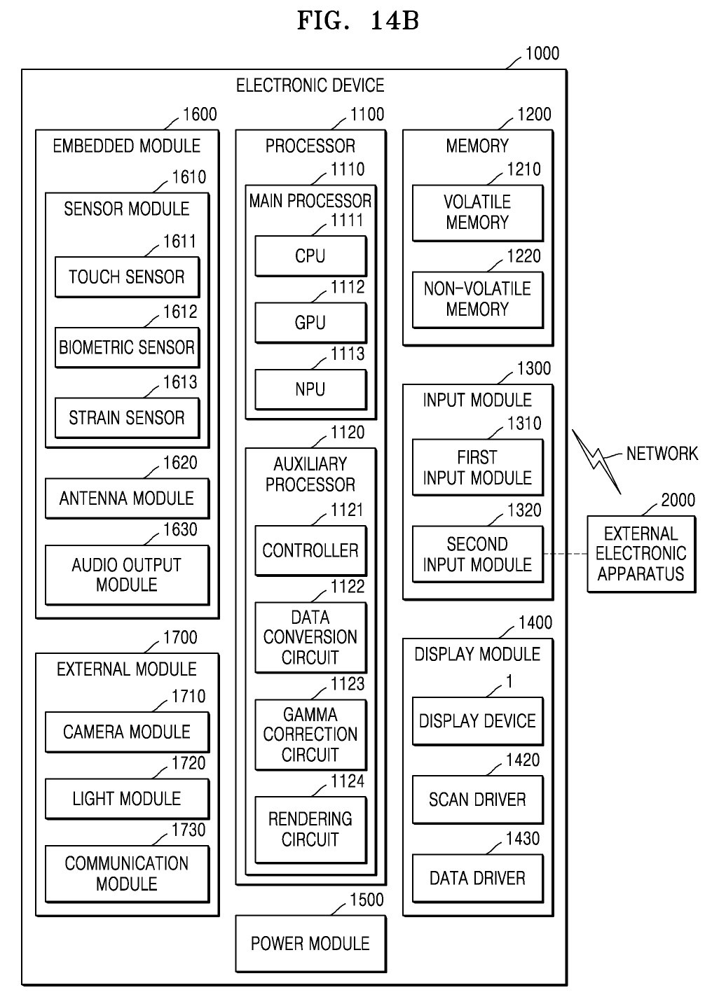

FIG. 14A is a schematic perspective view of an electronic apparatus 1000 including the display device 1, according to an embodiment of the present disclosure, and FIG. 14B is a schematic block diagram of the electronic apparatus 1000 including the display device 1, according to an embodiment of the present disclosure.

Referring to FIG. 14A, the electronic apparatus 1000 may be freely deformed in three dimensions, and may provide a three-dimensional image surface through the display area DA. The electronic apparatus 1000 being freely deformed in three dimensions is distinguished from an operation of an electronic apparatus having a rollable display device, such as the case where a rolled up portion of a display area is visible to a user, and then, as another rolled up portion of the display area is unfolded, the entire display area becomes visible to the user (or the case where the entire unfolded display area is visible to a user, and then, as the display area is rolled up, only a portion of the display area becomes visible to the user). The electronic apparatus 1000 according to embodiments of the present disclosure may exhibit deformation, for example, the entire area of the display area DA may increase or decrease as the electronic apparatus 1000 is deformed in the x-direction, the y-direction, and/or the z-direction.

Referring to FIG. 14B, the electronic apparatus 1000 may include a processor 1100, a memory 1200, an input module 1300, a display module 1400, a power module 1500, an embedded module 1600, and an external module 1700. According to an embodiment, the electronic apparatus 1000 may have at least one of the above-described components omitted therefrom, or one or more other components added thereto. According to an embodiment, some of the above-described components (e.g., the embedded module 1600) may be integrated into another component (e.g., the display module 1400).

The processor 1100 may execute software to control at least one other component (e.g., a hardware or software component) of the electronic apparatus 1000, which is connected to the processor 1100, and may perform various data processing or computations. According to an embodiment, as at least part of data processing or calculation, the processor 1100 may store commands or data received from another component (e.g., the input module 1300, a sensor module 1610, or a communication module 1730) in a volatile memory 1210, may process the commands or data stored in the volatile memory 1210, and may store resulting data in a non-volatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphic processing unit (GPU) 1112, a communication processor (CP), and an image signal processor (ISP). The main processor 1110 may further include a neural processing unit (NPU) 1113. The neural processing unit may be a processor specialized for processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the above, but is not limited to the above-described examples. The artificial intelligence model may additionally or alternatively include a software structure, in addition to a hardware structure. At least two of the above-described processing units and processors may be implemented as an integrated configuration (e.g., a single chip), or may each be implemented as an independent configuration (e.g., a plurality of chips).

The auxiliary processor 1120 may include a controller 1121. The controller 1121 may include an interface conversion circuit and a timing control circuit. The controller 1121 may receive an image signal from the main processor 1110, may convert the data format of the image signal to match interface specifications with the display module 1400, and may output image data. The controller 1121 may output various control signals supportive of driving the display module 1400.

The auxiliary processor 1120 may further include data processing circuits, such as a data conversion circuit 1122, a gamma correction circuit 1123, and a rendering circuit 1124. The data conversion circuit 1122 may receive image data from the controller 1121, and may compensate for the image data such that an image is displayed at a desired luminance according to characteristics of the electronic apparatus 1000 or user settings, or may convert the image data to reduce power consumption or compensate for afterimages. The gamma correction circuit 1123 may convert image data or a gamma reference voltage such that an image displayed on the electronic apparatus 1000 has desired gamma characteristics. The rendering circuit 1124 may receive image data from the controller 1121, and may render the image data by taking into account the pixel arrangement of the display device 1 applied to the electronic apparatus 1000. At least one of the data conversion circuit 1122, the gamma correction circuit 1123, and the rendering circuit 1124 may be integrated into another component (e.g., the main processor 1110 or the controller 1121). In an embodiment, the auxiliary processor 1120 may be integrated into a data driver 1430.

The memory 1200 may store various data used by at least one component of the electronic apparatus 1000 (e.g., the processor 1100 or the sensor module 1610) and input data or output data for commands related thereto. The memory 1200 may include at least one of the volatile memory 1210 and the non-volatile memory 1220.

The input module 1300 may receive commands or data to be used by a component of the electronic apparatus 1000 (e.g., the processor 1100, the sensor module 1610, or an audio output module 1630) from outside the electronic apparatus 1000 (e.g., a user or an external electronic apparatus 2000).

The input module 1300 may include a first input module 1310 into which commands or data is input from the user, and a second input module 1320 into which commands or data is input from the external electronic apparatus 2000.

The first input module 1310 may include a microphone, a mouse, a keyboard, or a pen (e.g., a passive pen or an active pen). The first input module 1310 may include a mechanical input means or a touch input means, such as a button, a dome switch, a jog wheel, or a jog switch, located on a rear surface or a side surface of the electronic apparatus 1000. The touch input means may include a touch screen layer of the display device 1.

The second input module 1320 may be connected by wire or wirelessly to various types of external electronic apparatuses 2000 connected to the electronic apparatus 1000. According to an embodiment, the second input module 1320 may include a high definition multimedia interface (HDMI), a universal serial bus (USB) interface, an SD card interface, or an audio interface. The second input module 1320 may include a connector that may physically connect the electronic apparatus 1000 to the external electronic apparatus 2000, for example, an HDMI connector, a USB connector, an SD card connector, or an audio connector (e.g., a headphones connector). In response to the external electronic apparatus 2000 being connected to the second input module 1320, the electronic apparatus 1000 may perform appropriate control related to the external electronic apparatus 2000 being connected.

The display module 1400 visually provides information to the user. The display module 1400 may include the display device 1, a scan driver 1420, and the data driver 1430.

The display device 1 displays (outputs) information processed by the electronic apparatus 1000. The display device 1 may display execution screen information of an application running on the electronic apparatus 1000, or user interface (UI) or graphic user interface (GUI) information according to the execution screen information.

The scan driver 1420 may be mounted on the display device 1 as a driving chip. Alternatively, the scan driver 1420 may be formed directly in the display device 1. For example, the scan driver 1420 may include an amorphous silicon TFT gate driver circuit (ASG), a low temperature-polycrystalline silicon (LTPS) TFT gate driver circuit, or an oxide semiconductor TFT gate driver circuit (OSG) internalized in the display device 1. The scan driver 1420 receives a control signal from the controller 1121, and outputs scan signals to the display device 1 in response to the control signal.

The display device 1 may further include an emission control driver. The emission control driver outputs an emission control signal to the display device 1 in response to a control signal received from the controller 1121. The emission control driver may be formed separately from the scan driver 1420, or may be integrated into the scan driver 1420.

The data driver 1430 receives a control signal from the controller 1121, converts image data into data voltages in the form of analog voltages in response to the control signal, and then outputs the data voltages to the display device 1.

The data driver 1430 may be integrated with some components of the auxiliary processor 1120. For example, the data driver 1430 may be provided as a timing controller embedded driver IC including the controller 1121.

The power module 1500 supplies power to the components of the electronic apparatus 1000. The power module 1500 may include a battery that is charged with a power voltage. In some aspects, the power module 1500 may have a connection port, and the connection port may be included in the second input module 1320 to which an external charger that supplies power for charging the battery is connected. Alternatively, the power module 1500 may include a wireless power transmission/reception member such that the battery may be charged wirelessly. The wireless power transmission/reception member may include a plurality of antenna radiators having a coil shape. The power module 1500 may include a power management integrated circuit (PMIC). The PMIC provides optimized power to each of the components of the electronic apparatus 1000.

The electronic apparatus 1000 may further include the embedded module 1600 and the external module 1700. The embedded module 1600 may include the sensor module 1610, an antenna module 1620, and the audio output module 1630. The external module 1700 may include a camera module 1710, a light module 1720, and/or the communication module 1730.

The sensor module 1610 may include touch electrodes and a touch sensor driving unit of a touch screen layer of the display device 1. The sensor module 1610 may sense an input by a user's body or an input by a pen, and may generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of the input by the user's body (e.g., a finger, etc.) or the input by the pen. The touch sensor 1611 may generate, as a data value, the amount of change in capacitance, the amount of change in pressure, or the amount of electromagnetic change due to the input.

The biometric sensor 1612 may generate a data value for recognizing a part of the user's body (e.g., the fingerprint, iris, face, etc.), or may generate a data value corresponding to body information (e.g., blood pressure, moisture, heart rate, body composition, etc.). The biometric sensor 1612 may use an optical method, an ultrasonic method, or a capacitive method.

The strain sensor 1613 may include layers, patterns, or wirings of which a measurable physical quantity changes according to stretching and recovery of the display device 1. For example, the strain sensor 1613 may include wirings of which the resistance and/or capacitance changes due to stretching and recovery of the display device 1. In another embodiment, the strain sensor 1613 may include an optical layer or optical pattern of which the transmittance and/or reflectance changes according to stretching and recovery of the display device 1.

Based on a change in physical quantity due to stretching and recovery of the display device 1, which is measured by the strain sensor 1613, the electronic apparatus 1000 may improve the quality of an image implemented in the display device 1 or control the display device 1. An operation of controlling the display device 1 may include, for example, an operation of displaying an operation image for protecting the display device 1, cutting off a voltage for driving the display device 1, or stopping a stretching and recovery operation of the display device 1.

In an embodiment, at least one of the touch sensor 1611, the biometric sensor 1612, and the strain sensor 1613 may be embedded in the display device 1. For example, at least one of the touch sensor 1611, the biometric sensor 1612, and the strain sensor 1613 may be formed through a process that is continuous with a process of forming a pixel driving circuit unit and/or a light-emitting element of the display device 1. As a result, the display device 1 may function as one of the input modules 1300 that provides an input interface between the electronic apparatus 1000 and the user, and may also function as the display module 1400 that provides an output interface between the electronic apparatus 1000 and the user.

In an embodiment, at least two of the touch sensor 1611, the biometric sensor 1612, and the strain sensor 1613 may be formed to be integrated into one sensing panel through the same process. In an embodiment, the sensing panel may be arranged between the display device 1 and a window cover arranged on a front surface of the display device 1, but embodiments of the present disclosure are not limited thereto.

The antenna module 1620 may include one or more antennas for transmitting or receiving signals or power to or from the outside. According to an embodiment, the communication module 1730 may transmit a signal to or receive a signal from an external electronic apparatus through an antenna appropriate for a communication method. An antenna pattern of the antenna module 1620 may be integrated into one component of the display module 1400 (e.g., the display device 1) or the biometric sensor 1612.

The audio output module 1630 may be a device for outputting an audio signal to the outside of the electronic apparatus 1000, and may output audio data received from the communication module 1730 or stored in the memory 1200, in a call signal reception mode, a call mode, a recording mode, a voice recognition mode, a broadcast reception mode, etc. The audio output module 1630 may output an audio signal related to a function performed in the electronic apparatus 1000 (e.g., a call signal reception sound, a message reception sound, etc.). The audio output module 1630 may include a receiver and a speaker. At least one of the receiver and the speaker may be an audio generation device that is attached to a rear surface of the display device 1 to vibrate the display device 1 and output sound. The audio generation device may be a piezoelectric element or a piezoelectric actuator that contracts and expands in response to an electrical signal, or may be an exciter that generates magnetic force by using a voice coil to vibrate the display device 1.

The camera module 1710 may capture a still image and a moving image. According to an embodiment, the camera module 1710 may include one or more lenses, image sensors, or image signal processors. The camera module 1710 may further include an infrared camera capable of measuring the presence or absence of a user, the user's location, the user's gaze, etc.

The light module 1720 may output a signal to notify the occurrence of an event by using light from a light source, or may provide light for image acquisition. Here, examples of the occurrence of an event may include message reception, call signal reception, missed call, alarm, schedule notification, email reception, battery charge capacity information notification, etc. The light module 1720 may include a light-emitting diode or a xenon lamp. The light module 1720 may emit light of a single color or multiple colors to a front surface or a rear surface of the electronic apparatus 1000. The light module 1720 may operate in conjunction with the camera module 1710, or may operate independently.

The communication module 1730 may support establishment of a wired or wireless communication channel between the electronic apparatus 1000 and the external electronic apparatus 2000, and performing of communication through the established communication channel. The communication module 1730 may include one or both of a wireless communication module, such as a cellular communication module, a short-range wireless communication module, or a global navigation satellite system (GNSS) communication module, and a wired communication module, such as a local area network (LAN) communication module or a power line communication module. The communication module 1730 may transmit or receive a wireless signal in an Internet network by using at least one of Wireless LAN (WLAN), Wireless-Fidelity (Wi-Fi), Wireless Fidelity (Wi-Fi) Direct, and Digital Living Network Alliance (DLNA) technologies. In some aspects, the communication module 1730 may support short-range communication by using at least one of Bluetooth™, Radio Frequency Identification (RFID), Infrared Data Association (IrDA), Ultra Wideband (UWB), ZigBee, Near Field Communication (NFC), Wireless-Fidelity (Wi-Fi), Wi-Fi Direct, and Wireless Universal Serial Bus (Wireless USB) technologies. The various types of communication modules 1730 described herein may be implemented as a single chip or as separate chips.

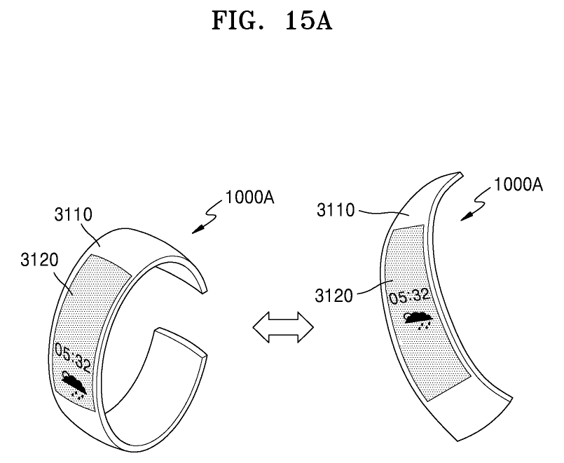

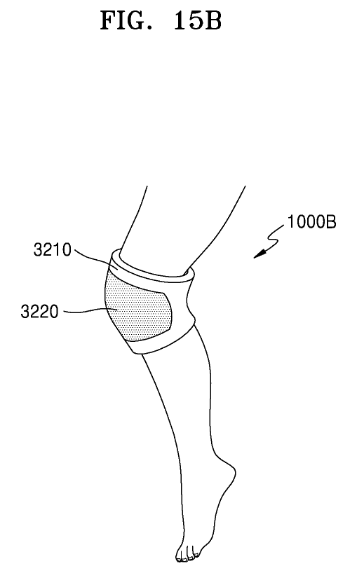

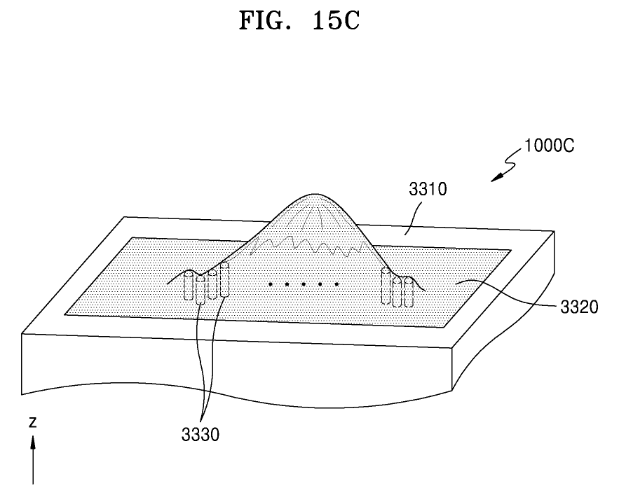

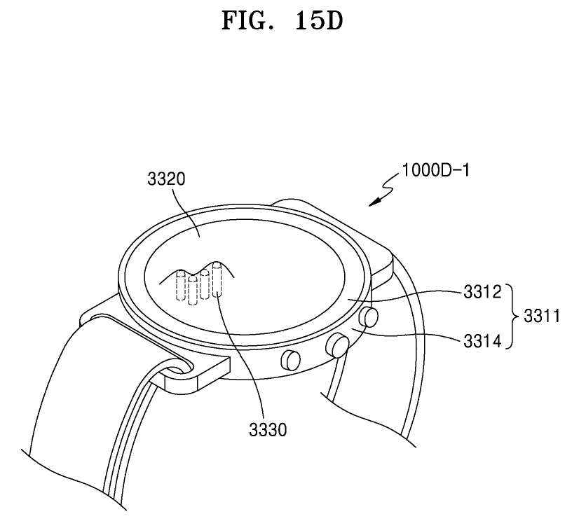

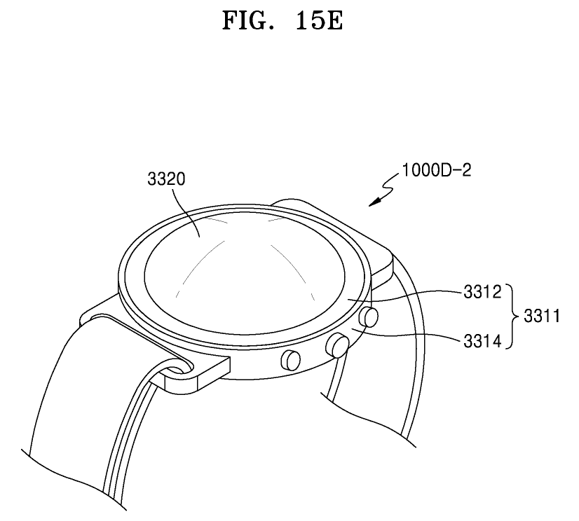

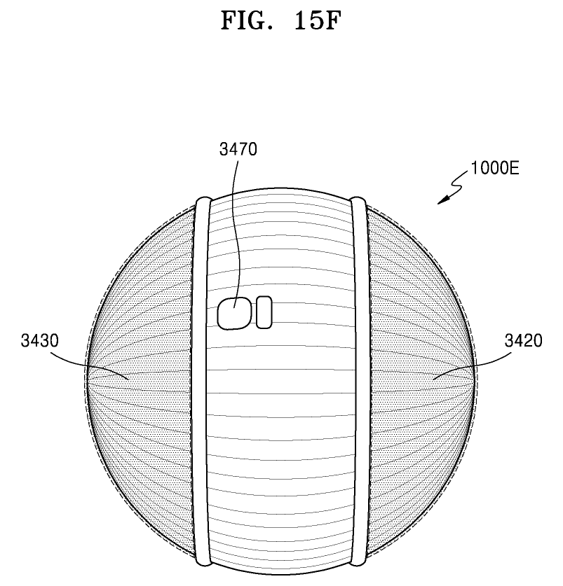

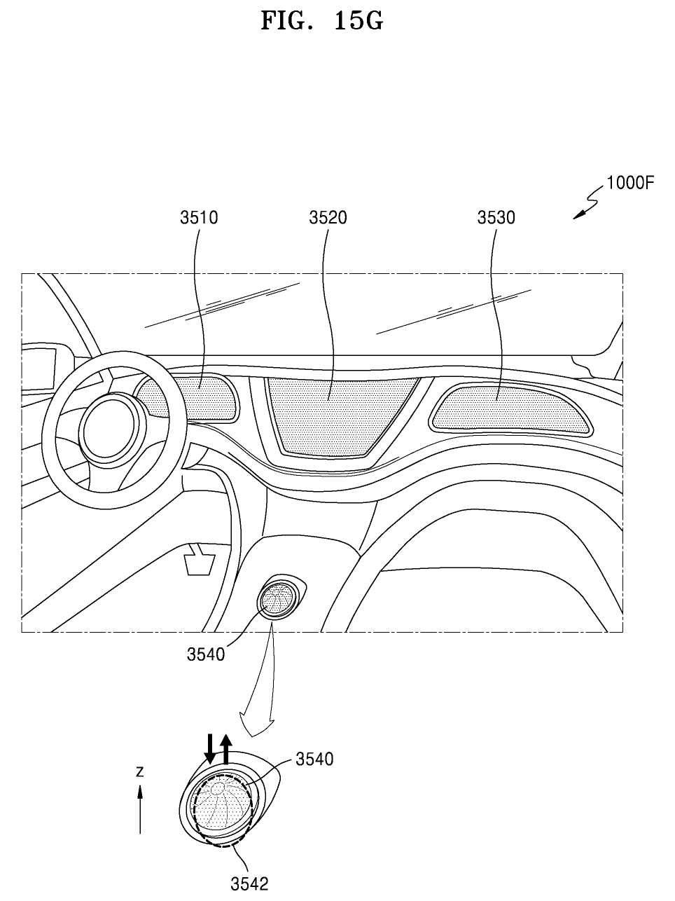

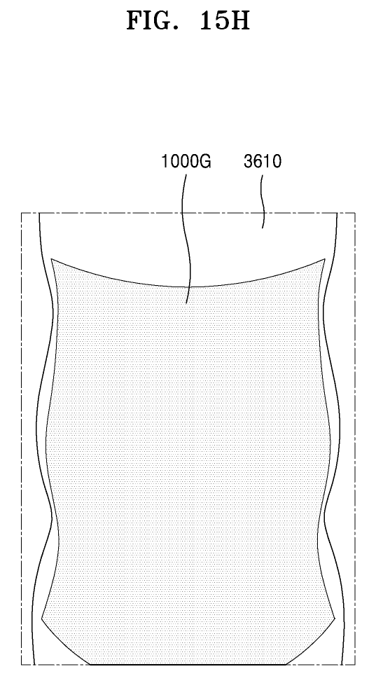

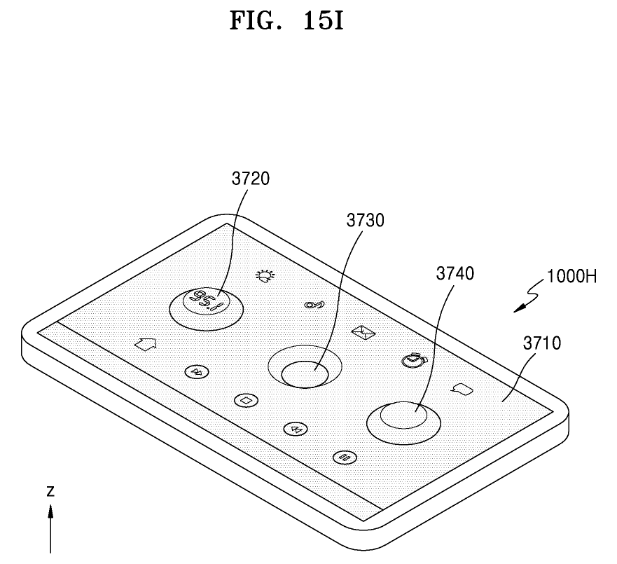

FIGS. 15A-15I are each a schematic perspective view of an embodiment of an electronic apparatus including a display device, according to an embodiment of the present disclosure.

Referring to FIG. 15A, a display device according to an embodiment of the present disclosure may be used in a wearable electronic apparatus 1000A that may be worn on a part of a user's body. The wearable electronic apparatus 1000A may include a body portion 3110 and a display unit 3120 provided on the body portion 3110. The display device according to embodiments of the present disclosure may be used as the display unit 3120 of the wearable electronic apparatus 1000A. As illustrated in FIG. 15A, the wearable electronic apparatus 1000A may be deformable. In an embodiment, the wearable electronic apparatus 1000A may be used as a smart watch or a smartphone according to the user's choice.

FIG. 15B illustrates a medical electronic apparatus 1000B. In an embodiment, the medical electronic apparatus 1000B may include a body portion 3210 and an emission unit 3220. A display device according to embodiments of the present disclosure may be used as the emission unit 3220 of the medical electronic apparatus 1000B. The emission unit 3220 may emit light of a certain wavelength band (e.g., infrared light, visible light, etc.) to a patient's body. In an embodiment, the body portion 3210 may include a stretchable and recoverable fiber material, and may have a structure that may be worn on a user's body.

FIG. 15C illustrates an educational electronic apparatus 1000C. In an embodiment, the educational electronic apparatus may include a display unit 3320 provided within a housing 3310. The display unit 3320 may use a display device according to embodiments of the present disclosure. The display unit 3320 may provide an image of a sea with waves, a mountain covered in snow, or a volcano with flowing lava, and in this case, the display unit 3320 may be stretched in a height direction (e.g., the z-direction) to reflect the height of the waves, the mountain, or the volcano. In some embodiments, the height of a portion of the display unit 3320 may sequentially vary in a direction in which the lava flows, thereby displaying movement of the lava in three dimensions. The educational electronic apparatus 1000C may include a plurality of pins (or stroke portions) 3330 arranged on a rear surface of the display unit 3320 such that the display unit 3320 is stretched in the height direction. As the pins 3330 move in the third direction (e.g., the z-direction or the -z-direction), an image expressed on the display unit 3320 may be implemented to have a three-dimensional height. Although FIG. 15C illustrates an educational electronic apparatus 1000C, the use thereof is not limited as long as it provides certain image information.

FIGS. 15D and 15E show display devices being used in wearable electronic apparatuses 1000D-1 and 1000D-2, such as smart watches.

In an embodiment, as illustrated in FIG. 15D, the display device corresponding to a display unit 3320 of the electronic apparatus 1000D-1 may be three-dimensionally stretchable, and thus may provide a user with various haptic information, in addition to visual information through an image. In an embodiment, the electronic apparatus 1000D-1 may provide haptic information, such as Braille markings for the visually impaired or tactile stimulation linked to an image, by using a plurality of pins (or stroke portions) 3330 arranged below the display unit 3320. The display device forming the display unit 3320 may be three-dimensionally stretchable, and thus may provide the above-described haptic information to the user. The electronic apparatus 1000D-1 may include a body portion 3311 including a housing 3314 accommodating the display device forming the display unit 3320 and the pins (or stroke portions) 3330, and a frame 3312 that may be coupled to the housing 3314 with the display device therebetween. In some embodiments, the frame 3312 may be formed as a single body with the housing 3314.

The electronic apparatus 1000D-2 of FIG. 15E may include a body portion 3311 and a display unit 3320 that is accommodated in the body portion 3311 and capable of providing visual information, as in FIG. 15D. In some embodiments, the display device corresponding to the display unit 3320 may be three-dimensionally stretchable, and thus, the electronic apparatus 1000D-2 may include a display unit 3320 having a dome shape. In an embodiment, in a manufacturing process of the electronic apparatus 1000D-2, the display device may be assembled on a dome-shaped body frame, and in this case, the display device may be three-dimensionally stretchable, and thus may be assembled in a stretched state along the shape of a hemispherical body frame.

FIG. 15F illustrates an electronic apparatus 1000E including a robot, according to an embodiment of the present disclosure. The robot may recognize a movement or an object by using a camera module 3470, and may display a certain image to a user on display units 3420 and 3430.

In some embodiments, display devices according to an embodiment of the present disclosure may be stretched in various directions as described herein, and thus may be assembled on a body frame having a hemispherical shape, and accordingly, the robot may include display units 3420 and 3430 having a hemispherical shape.

FIG. 15G illustrates a vehicle display apparatus 1000F as an electronic apparatus according to an embodiment of the present disclosure. The vehicle display apparatus 1000F may include a cluster 3510, a center information display (CID) 3520, and/or a co-driver display 3530. A display device according to an embodiment of the present disclosure may be stretched in various directions, and thus may be used in the cluster 3510, the CID 3520, and/or the co-driver display 3530, regardless of the shape of an internal frame of the vehicle.

FIG. 15G illustrates that the cluster 3510, the CID 3520, and/or the co-driver display 3530 are separated from each other, but embodiments of the present disclosure are not limited thereto. In another embodiment, two or more selected from the cluster 3510, the CID 3520, and the co-driver display 3530 may be connected into a single body.

In some embodiments, the vehicle display apparatus 1000F may include a button 3540 capable of expressing a certain image. Referring to the enlarged view of FIG. 15G, the button 3540 having a hemispherical shape may include an object 3542 that provides a feeling of use of the button 3540 while moving in the z-direction or the -z-direction, and a display device arranged on the object 3542. In some embodiments, when the object 3542 has a three-dimensionally round surface, the display device may also have a three-dimensionally round surface.

FIG. 15H illustrates an electronic apparatus 1000G for advertising or exhibition as an electronic apparatus according to an embodiment of the present disclosure. In some embodiments, the electronic apparatus 1000G for advertising or exhibition may be installed on a structure 3610 that is fixed, such as a wall or a pillar. In an example in which the structure 3610 includes an uneven surface as illustrated in FIG. 15H, the electronic apparatus 1000G for advertising or exhibition may be arranged along the uneven surface of the structure 3610. In some embodiments, the electronic apparatus 1000G for advertising or exhibition may be installed on the structure 3610 by using a heat-shrink film, etc.

FIG. 15I illustrates a controller as an electronic apparatus 1000H according to an embodiment of the present disclosure. The controller may include an image-type button. For example, the controller may include first to third button areas 3720, 3730, and 3740 in which portions of a display unit 3710 protrude in the z-direction or protrude in the -z-direction (or are recessed in the z-direction). In some embodiments, the first and third button areas 3720 and 3740 may protrude in the z-direction, and the second button area 3730 may protrude in the -z-direction (or be recessed in the z-direction).

While the present disclosure has been described with reference to the embodiments illustrated in the drawings, these are examples, and those skilled in the art will understand that various modifications and equivalent other embodiments are possible therefrom. Therefore, the true technical protection scope of the present disclosure should be determined by the technical spirit of the appended claims.

According to one or more embodiments of the present disclosure, a display device and an electronic apparatus, in which space efficiency may be improved and a sealing structure of an encapsulation layer may be stably maintained, may be provided.

Such effects are examples, and the scope of the present disclosure is not limited to the above effects.

It should be understood that embodiments described herein should be considered in a descriptive sense and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display device comprising:
a first island portion;
a plurality of first bridge portions extending in different directions from the first island portion;
a substrate comprising a first portion corresponding to the first island portion and a plurality of second portions corresponding to the plurality of first bridge portions;
a pixel driving circuit arranged on the first portion of the substrate;
a light-emitting element arranged on the pixel driving circuit and comprising:
a first electrode electrically connected to the pixel driving circuit;
a second electrode arranged on the first electrode; and
an intermediate layer arranged between the first electrode and the second electrode;
a first inorganic encapsulation layer arranged on the light-emitting element;
a first layer interposed between the pixel driving circuit and the first electrode of the light-emitting element and comprising an inorganic insulating material; and
a second layer arranged on the first layer and comprising:
a portion extending in a direction away from an upper surface of the first layer;
a first surface facing the first layer; and
a second surface opposite to the first surface,
wherein the first surface is in direct contact with the first inorganic encapsulation layer.

2. The display device of claim 1, wherein the second layer comprises an inorganic insulating material.

3. The display device of claim 1, wherein the second layer comprises a metal material.

4. The display device of claim 3, wherein the second electrode of the light-emitting element extends toward the second layer and is in direct contact with a portion of the first surface of the second layer.

5. The display device of claim 3, wherein the second layer has a constant voltage level.

6. The display device of claim 1, wherein, when viewed in a direction perpendicular to the substrate, the second layer has a frame shape extending along an edge of the first island portion.

7. The display device of claim 1, wherein a first angle between the portion of the second layer and the upper surface of the first layer is about 45 degrees or less.

8. The display device of claim 1, wherein:
the upper surface of the first layer faces the first surface of the second layer, and
the first inorganic encapsulation layer extends continuously and covers the first surface of the second layer and the upper surface of the first layer.

9. The display device of claim 1, further comprising:
an organic encapsulation layer on the first inorganic encapsulation layer; and
a second inorganic encapsulation layer on the organic encapsulation layer,
wherein the second inorganic encapsulation layer is in direct contact with the first inorganic encapsulation layer on the first surface of the second layer.

10. The display device of claim 9, wherein the first inorganic encapsulation layer and the second inorganic encapsulation layer:
extend toward the plurality of first bridge portions, and
are in direct contact with each other on the plurality of second portions of the substrate.

11. The display device of claim 1, wherein a peripheral portion of the first layer extends in a direction away from the first surface of the second layer.

12. An electronic apparatus comprising:
a display unit;
a frame; and
a display device which is assembled to the frame, corresponds to the display unit, and comprises:
a first island portion;
a plurality of first bridge portions extending in different directions from the first island portion;
a substrate comprising a first portion corresponding to the first island portion and a plurality of second portions corresponding to the plurality of first bridge portions;
a pixel driving circuit arranged on the first portion of the substrate;
a light-emitting element arranged on the pixel driving circuit and comprising:
a first electrode electrically connected to the pixel driving circuit;
a second electrode arranged on the first electrode; and
an intermediate layer arranged between the first electrode and the second electrode;
a first inorganic encapsulation layer arranged on the light-emitting element;
a first layer interposed between the pixel driving circuit and the first electrode of the light-emitting element; and
a second layer arranged on the first layer and comprising:
a portion extending upward from a first point;
a first surface facing the first layer; and
a second surface opposite to the first surface,
wherein the first surface is in direct contact with the first inorganic encapsulation layer.

13. The electronic apparatus of claim 12, further comprising a stroke assembled to the frame and arranged between the display device and the frame.

14. The electronic apparatus of claim 12, wherein the second layer comprises an inorganic insulating material.

15. The electronic apparatus of claim 12, wherein the second layer comprises a metal material and has a constant voltage level.

16. The electronic apparatus of claim 12, wherein the second electrode of the light-emitting element extends toward the second layer and is in direct contact with a portion of the first surface of the second layer.

17. The electronic apparatus of claim 12, wherein, when viewed in a direction perpendicular to the substrate, the second layer has a frame shape extending along an edge of the first island portion.

18. The electronic apparatus of claim 12, wherein a peripheral portion of the second layer extends downward.

19. The electronic apparatus of claim 12, wherein:
the first layer comprises a first surface facing the first surface of the second layer, and
the first inorganic encapsulation layer extends continuously and covers the first surface of the second layer and the first surface of the first layer.

20. The electronic apparatus of claim 12, wherein the display device further comprises:
an organic encapsulation layer on the first inorganic encapsulation layer; and
a second inorganic encapsulation layer on the organic encapsulation layer,
wherein the second inorganic encapsulation layer is in direct contact with the first inorganic encapsulation layer on the first surface of the second layer, and
wherein the first inorganic encapsulation layer and the second inorganic encapsulation layer extend toward the plurality of first bridge portions, and are in direct contact with each other on the plurality of second portions of the substrate.
